(19) United States
(12) Patent Application Publication
(10) Pub. No.: US 2026/0258169 A1
(43) Pub. Date: Sep. 3, 2026

(54) ELECTROACTIVE POLYMER, METHODS FOR THE MANUFACTURE THEREOF, AND USE FOR ELECTROCHEMICAL GAS SEPARATION

(71) Applicant: Verdox, Inc., Woburn, MA (US)

(72) Inventor: Cameron Rogers, Malden, MA (US)

(21) Appl. No.: 19/164,851

(22) PCT Filed: May 17, 2024
(86) PCT No.: PCT/US2024/029865

§ 371 Date: Sep. 12, 2025

Related U.S. Application Data
(60) Provisional application No. 63/468,043, filed on May 22, 2023.

(51) Int. Cl. C08F 32/08; B01D 53/32; B01D 53/62; H01M 4/60

(52) U.S. Cl. CPC C08F 32/08; B01D 53/326; B01D 53/62; H01M 4/608; B01D 2257/504; C08F 2810/20

(57) ABSTRACT

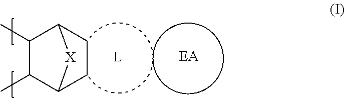

An electroactive polymer includes repeating units of Formula (I) wherein X, L, and EA are as defined herein. Methods of manufacturing the electroactive polymer are also disclosed. The electroactive polymer can be useful in composites, electrode assemblies, electrochemical cells, gas separation systems, energy storage devices, and electrochromic devices.

### CROSS-REFERENCE TO RELATED APPLICATION

This application claims priority to U.S. Provisional Patent Application No. 63/468,043, filed on May 22, 2023, the contents of which are hereby incorporated by reference in their entirety.

### BACKGROUND

Removing target species from gas mixtures has been the subject of much research and development. For example, there have been efforts to mitigate global warming by curbing carbon dioxide emissions. To this end, a number of approaches, such as thermal methods have been explored, to capture carbon dioxide at different stages of its production. Other potential applications of target gas removal include removing target gasses directly from air or ventilated air.

Electro-swing adsorption (ESA) is an alternative method of capturing a target gas from a gaseous mixture. Typically, the electrode in an electro-swing adsorption cell includes an electrically conductive scaffold and an electroactive material. There remains a need for improved materials for electro-swing adsorption, including improved methods of production.

### SUMMARY

An electroactive polymer comprises repeating units of Formula (I)

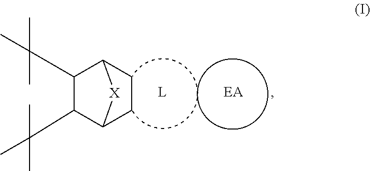

wherein X is —CH₂— or —O—; L is an optional fused C₄₋₆ cycloalkyl linking group or an optional fused benzene linking group; and EA is an electroactive species having an oxidized state, and at least one reduced state.

A method of making an electroactive polymer comprises polymerizing an electroactive monomer of Formula (XIV)

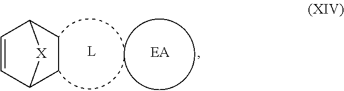

under conditions effective to provide an electroactive polymer comprising repeating units of Formula (I)

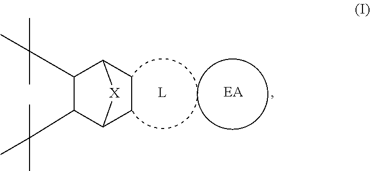

wherein in the foregoing Formulas, X is —CH₂— or —O—; L is an optional fused C₄₋₆ cycloalkyl linking group or an optional fused benzene linking group; and EA is an electroactive species having at least one oxidized state, and at least one reduced state.

Another aspect of the present disclosure is a composite comprising the electroactive polymer.

Another aspect of the present disclosure is an electrode assembly comprising: a porous separator; and the composite on a surface of the porous separator, in a pore of the porous separator, or a combination thereof.

Another aspect of the present disclosure is an electrode assembly comprising a current collector; and the composite on a surface of the current collector.

Another aspect is an electrochemical cell comprising the composite.

Another aspect is a gas separation system comprising a plurality of electrochemical cells in fluid communication with a gas inlet and a gas outlet, wherein each of the plurality of electrochemical cells comprises the composite comprising the electroactive polymer.

Another aspect is an electrochemical cell comprising the electroactive polymer.

Another aspect is an energy storage device or an electrochromic device comprising the electroactive polymer.

A method for separating a target gas from a fluid mixture comprising the target gas comprises contacting the fluid mixture with an electroactive polymer comprising repeating units according to Formula (I), wherein the electroactive polymer is in a reduced state, to form an anion adduct between the target gas and the electroactive polymer in the reduced state to separate the target gas from the fluid mixture.

The above described and other features are exemplified by the following figures and detailed description.

### BRIEF DESCRIPTION OF THE DRAWINGS

The following figures are exemplary embodiments.

FIG. 1 is a chemical scheme illustrating polymerization of a quinone-containing norbornene monomer according to Example 1.

FIG. 2 is a chemical scheme illustrating copolymerization of a quinone-containing norbornene monomer according to Example 2.

### DETAILED DESCRIPTION

Several electroactive polymers have been explored as electroactive materials, particularly those including quinone moieties, which can switch between oxidized and reduced states having differing affinities for a target gas. It has been found that certain electroactive polymers can be prepared by an addition or alkene insertion polymerization process at a double bond of a cyclic electroactive monomer. Such processes afford polymers having a different architecture compared to polymers formed from the same cyclic electroactive monomers but prepared using a ring opening metathesis polymerization (ROMP) process, for example as in International Application No. PCT/US2022/050836, the content of which is incorporated herein by reference in its entirety. Extension of new polymerization methodologies to polymers containing electroactive moieties affords ready access to a versatile class of electroactive polymers. For example, certain electroactive polymers, particularly those including quinone moieties, have been previously shown to not tolerate certain polymerization catalysts or other reaction conditions. It would be advantageous to provide a polymerization method that is more tolerant of a wider range of polymerization conditions including solvents and catalysts, as well as the presence of various functional groups on the monomers. Different polymer backbone structures can also provide different mechanical properties, polymer stability, and solubility. Further, it can be desirable to provide copolymers with monomers that are not amenable to ROMP (e.g., non-cyclic olefin monomers such as ethylene). Accordingly, there remains a continuing need in the art for alternative synthetic approaches to further enable the use of electroactive polymers, in particular for ESA applications.

The present inventor has surprisingly discovered that electroactive polymers can be prepared using addition or alkene insertion type polymerizations to afford electroactive polymers with a saturated backbone. The electroactive polymers of the present disclosure can be particularly useful for a variety of electrochemical applications, including, but not limited to, energy storage, electrochromic applications, gas separation, catalysis, and oxygen reduction. In a specific aspect, the electroactive polymers can be used in electrode assemblies, electrochemical cells, and gas separation systems to separate a target gas (e.g., CO₂ or SO₂) from a gas mixture by an electrochemical process. Thus, a significant improvement is provided by the present disclosure.

Accordingly, an aspect of the present disclosure is an electroactive polymer. The electroactive polymer comprises repeating units according to Formula (I)

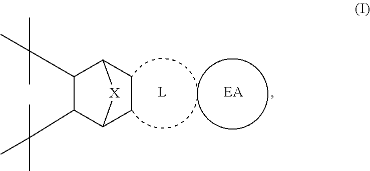

wherein X is —CH₂— or —O—; L is an optional fused C₄₋₆ cycloalkyl linking group or an optional fused benzene linking group; and EA is an electroactive species.

The electroactive polymer comprises at least 5 repeating units according to Formula (I), or at least 10 repeating units according to Formula (I). For example, the electroactive polymer can comprise 5 to 1000 units, or 5 to 750 units, or 5 to 500 units, or 5 to 250 units, or 10 to 1000 repeating units, 10 to 750 units, or 10 to 500 units, or 10 to 250 units, or 10 to 100 units. In an aspect, the electroactive polymer can comprise 10 to 75 repeating units, or 10 to 50 repeating units, or 10 to 30 repeating units or 10 to 25 repeating units according to Formula (I).

As shown in Formula (I), the electroactive polymer comprises repeating units wherein an electroactive species is fused to a cyclic olefin, optionally including an intermediary fused ring between the cyclic olefin and the electroactive species shown as “L” in Formula (I). It will be understood that when L is not present, the EA electroactive species is directly bound or fused to the cyclic olefin. The double bond of the cyclic olefin enables polymerization by addition across the double bond or by alkene insertion polymerization. Polymerization of the cyclic olefin provides a saturated hydrocarbon polymer backbone.

In an aspect, the electroactive species is a moiety which has at least one oxidized state and at least one reduced state. The at least one reduced state of the electroactive species can be reactive towards a target species. As will be understood by the skilled person, the reactivity of the electroactive species in the reduced state towards a target species will depend on the particular application and the chemical identity of the target species. For example, the electroactive species can have at least one oxidized state and at least one reduced state, wherein the at least one reduced state is capable of bonding with a target species to form an anion adduct between the target species and the reduced electroactive species. In an aspect, the electroactive species is a moiety which has at least one oxidized state or at least one reduced state. For example, electroactive species having two or more oxidized states or two or more reduced states are contemplated by the present disclosure.

The electroactive active species can comprise, for example, a quinone or a pyrazine group.

In an aspect, the electroactive species comprises a quinone group and the electroactive polymer comprises repeating units according to at least one of Formulas (II) to (V)

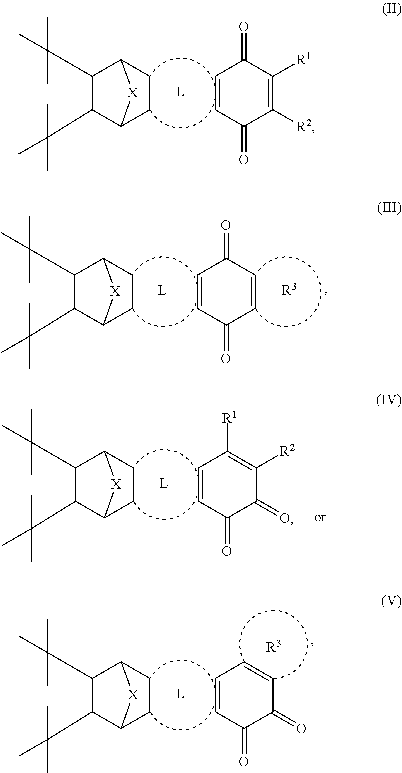

wherein X is —CH₂— or —O—; L is an optional fused C₄₋₆ cycloalkyl linking group or an optional fused benzene linking group; R¹ and R² are independently at each occurrence hydrogen, halogen, a substituted or unsubstituted C₁₋₆ alkyl group, a substituted or unsubstituted C₁₋₃₀ alkoxy group, a poly(C₁₋₃₀ alkylene oxide) group, a substituted or unsubstituted C₃₋₃₀ cycloalkyl group, a substituted or unsubstituted C₆₋₃₀ aryl group, a substituted or unsubstituted C₆₋₃₀ heteroaryl group, a nitrile group, a nitro group, a thiol group, an amine group, an amide group, an ester group, or a ketone group; and R³ is an optional fused substituted or unsubstituted aryl group. It will be understood that the optional groups indicated by the dashed lines in the foregoing Formulas may or may not be present. When the optional L group is not present, it will be understood that the quinone ring and the cyclic moiety of the polymer backbone are directly fused.

The identity of R¹ and R² can be influenced by the conditions used to prepare the electroactive polymers comprising the quinones. For example, some functional groups, such as thiols or amines, may poison certain polymerization catalysts or initiators and not others. The skilled person knows how to select suitable functional groups for substituents R¹ and R² guided by the present disclosure and based on the functional group tolerance of the catalyst selected to prepare the electroactive polymer. In an aspect, a catalyst can be selected in view of the desired R¹ and R² groups. The skilled person knows how to select a suitable catalyst guided by the present disclosure and based on the functional group tolerance in view of the identity of R¹ and R².

In an aspect, L is not present, and the electroactive polymer can comprise repeating units according to at least one of Formulas (IIa) to (Va)

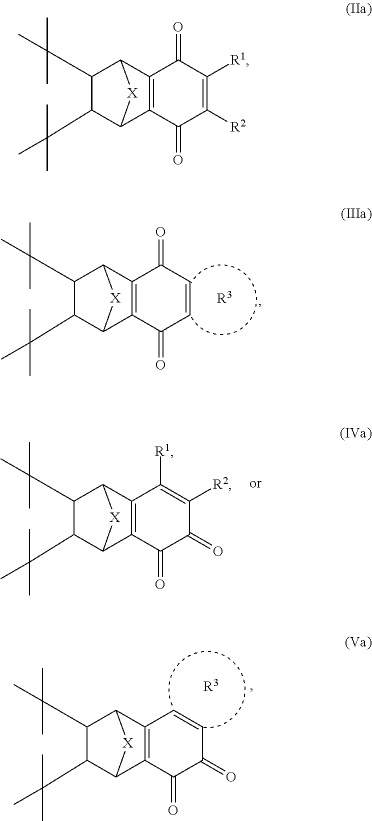

wherein X, R¹, R², and R³ are as defined above.

In an aspect, the electroactive polymer can comprise repeating units according to Formula (IIa), wherein R¹ and R² are each hydrogen and X is —CH₂—. In an aspect, the electroactive polymer can comprise repeating units according to Formula (IIa), wherein R¹ and R² are each hydrogen and X is —O—.

In an aspect, the electroactive polymer can comprise repeating units according to Formula (IIa), wherein R¹ and R² are each halogen, preferably chlorine, and X is —CH₂—. In an aspect, the electroactive polymer can comprise repeating units according to Formula (IIa), wherein R¹ and R² are each halogen, preferably chlorine, and X is —O—.

In an aspect, the electroactive polymer can comprise repeating units according to Formula (IIa) wherein R¹ and R² are each methyl and X is —CH₂—. In an aspect, the electroactive polymer can comprise repeating units according to Formula (IIa) wherein R¹ and R² are each methyl and X is —O—.

In an aspect, the electroactive polymer can comprise repeating units according to Formula (IIIa), wherein R³ is a substituted or unsubstituted fused benzene group and X is —CH₂—. In an aspect, the electroactive polymer can comprise repeating units according to Formula (IIIa), wherein R³ is a substituted or unsubstituted fused benzene group and X is —O—. In an aspect, R³ can be an unsubstituted fused benzene group. In an aspect R³ is a fused benzene group substituted with 1 to 4 chlorine groups, preferably a tetrachloro-substituted fused benzene group.

In an aspect, the electroactive polymer can comprise repeating units according to Formula (IIIa), wherein R³ is a substituted or unsubstituted fused naphthyl group and X is —CH₂—. In an aspect, the electroactive polymer can comprise repeating units according to Formula (IIIa), wherein R³ is a substituted or unsubstituted fused naphthyl group and X is —O—. In an aspect, R³ can be an unsubstituted fused naphthyl group.

In an aspect, L can be present. For example, the electroactive polymer can comprise repeating units wherein L is present and is a fused C₄₋₆ cycloalkyl linking group, for example a fused cyclobutane group, a fused cyclopentane group, or a fused cyclohexane group. In an aspect, the electroactive polymer can comprise repeating units wherein L is present and is a fused benzene linking group.

In an aspect, the electroactive polymer can be according to Formula (III), wherein L is present and is a cyclobutane group, R³ is present and is a substituted or unsubstituted fused benzene group, preferably an unsubstituted fused benzene group, and X is —CH₂—. In an aspect, the electroactive polymer can be according to Formula (III), wherein L is present and is a cyclobutane group, R³ is present and is substituted or unsubstituted fused benzene group, preferably an unsubstituted fused benzene group, and X is —O—. Accordingly, the electroactive polymer can comprise repeating units of the structure

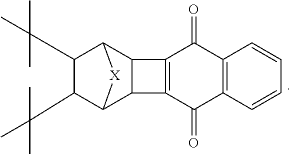

In an aspect, the electroactive polymer can be according to Formula (III), wherein L is present and is a phenyl group, R³ is present and is a substituted or unsubstituted fused benzene group, preferably an unsubstituted fused benzene group, and X is —CH₂—. In an aspect, the electroactive polymer can be according to Formula (III), wherein L is present and is a cyclobutane group, R³ is present and is a substituted or unsubstituted fused benzene group, preferably an unsubstituted fused benzene group, and X is —O—. Accordingly, the electroactive polymer can comprise repeating units of the structure

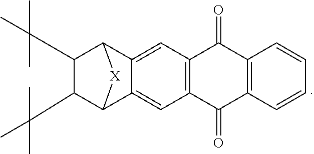

In an aspect, the electroactive species comprises a pyrazine group. For example, the electroactive polymer can comprise repeating units according to at least one of Formulas (VI) to (VII)

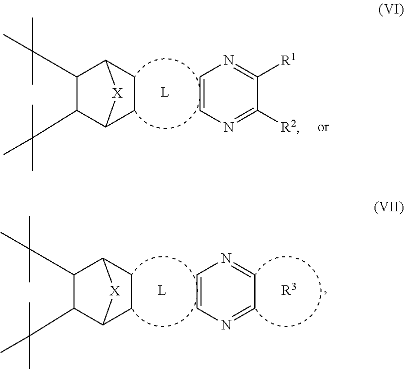

wherein X is —CH₂— or —O—; L is an optional fused C₄₋₆ cycloalkyl linking group or an optional fused benzene linking group; R¹ and R² are independently at each occurrence hydrogen, halogen, a substituted or unsubstituted C₁₋₆ alkyl group, a substituted or unsubstituted C₁₋₃₀ alkoxy group, a poly(C₁₋₃₀ alkylene oxide) group, a substituted or unsubstituted C₃₋₃₀ cycloalkyl group, a substituted or unsubstituted C₆₋₃₀ aryl group, a substituted or unsubstituted C₆₋₃₀ heteroaryl group, a nitrile group, a nitro group, a thiol group, an amine group, an amide group, an ester group, or a ketone group; and R³ is a fused substituted or unsubstituted aryl group. The optional groups indicated by the dashed lines may or may not be present. When the optional L group is not present, it will be understood that the pyrazine ring and the cyclic group of the polymer backbone are directly fused.

The identity of R¹ and R² can be influenced by the conditions used to prepare the electroactive polymers comprising the pyrazine. For example, some functional groups, such as thiols or amines, may poison certain polymerization catalysts or initiators and not others. Thus, the skilled person would know how to select suitable functional groups for substituents R¹ and R² guided by the present disclosure and based on the functional group tolerance of the catalyst selected to prepare the electroactive polymer. In an aspect, a catalyst can be selected in view of the desired R¹ and R² groups. The skilled person knows how to select a suitable catalyst guided by the present disclosure and based on the functional group tolerance in view of the identity of R¹ and R².

In an aspect, L is not present, and the electroactive polymer can comprise repeating units according to at least one of Formula (VIa) to (VIIa)

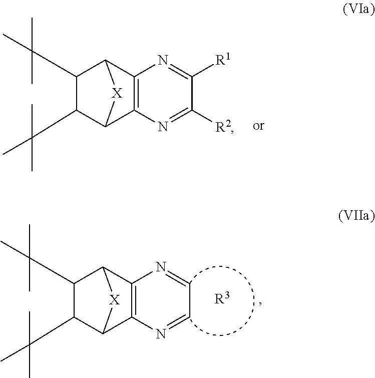

wherein X, R¹, R², and R³ are as defined above.

In an aspect, the electroactive polymer can comprise repeating units according to Formula (VIa), wherein R¹ and R² are each hydrogen and X is —CH₂—. In an aspect, the electroactive polymer can comprise repeating units according to Formula (VIa), wherein R¹ and R² are each hydrogen and X is —O—.

In an aspect, the electroactive polymer can comprise repeating units according to Formula (VIa), wherein R¹ and R² are each a nitrile group and X is —CH₂—. In an aspect, the electroactive polymer can comprise repeating units according to Formula (VIa), wherein R¹ and R² are each a nitrile group and X is —O—.

In an aspect, the electroactive polymer can comprise repeating units according to Formula (VIa), wherein R¹ and R² are each a substituted or unsubstituted phenyl group and X is —CH₂—. In an aspect, the electroactive polymer can comprise repeating units according to Formula (VIa), wherein R¹ and R² are each a substituted or unsubstituted phenyl group and X is —O—. In an aspect, R¹ and R² are each an unsubstituted phenyl group.

In an aspect, L is present. For example, the electroactive polymer can comprise repeating units wherein L is present and is a fused C₄₋₆ cycloalkyl linking group, for example a fused cyclobutane group, cyclopentane group, or cyclohexane group. In an aspect, the electroactive polymer can comprise repeating units wherein L is present and is a fused benzene linking group.

In an aspect, the electroactive polymer is according to Formula (VI), wherein L is present and is a phenyl group, R¹ and R² are each hydrogen, and X is —CH₂—. In an aspect, the electroactive polymer can comprise repeating units according to Formula (VI), wherein L is present and is a phenyl group, R¹ and R² are each hydrogen and X is —O—.

In an aspect, at least 10 mole percent, or at least 20 mole percent, or at least 30 mole percent, or at least 40 mole percent, or at least 50 mole percent, or at least 75 mole percent, or at least 80 mole percent, or at least 90 mole percent, or at least 95 mole percent, or at least 99 mole percent, e.g., 50 mole percent to 99.9 mole percent, or 75 mole percent to 95 mole percent, of the repeating units of the electroactive polymer are according to Formula (I), or, more specifically, or any one or more of Formulas (II)-(VII). In an aspect, the electroactive polymer consists of repeating units according to Formula (I), or, more specifically, or any one or more of Formulas (II)-(VII). In an aspect, the electroactive polymer can be a homopolymer having a single type of repeating unit according to Formula (I), for example, a homopolymer of any of the repeating units according to Formulas (II) to (VII). In an aspect, the electroactive polymer can comprise or consist of a combination of repeating units according to any one or more of Formulas (II) to (VII).

In an aspect, the electroactive polymer can be a copolymer further comprising one or more repeating units different from the repeating units of Formula (I), or, more specifically, different from any one or more of Formulas (II)-(VII). When the repeating units different from the repeating units according to Formula (I) are present, they can be included in the electroactive polymer in an amount of at most 90 mole percent, or at most 80 mole percent, or at most 70 mole percent, or at most 60 mole percent, or at more 50 mole percent, or at most 25 mole percent, or at most 20 mole percent, or at most 10 mole percent, or at most 5 mole percent, e.g., 0.1, 1, or 2 mole percent to 5, 10, or 20 mole percent. In an aspect, the repeating units different from the repeating units according to Formula (I) can be included in an amount of 1 to 50 mole percent, or 5 to 40 mole percent, or 5 to 35 mole percent, or 10 to 30 mole percent, or 15 to 25 mole percent.

The additional repeating units different from Formula (I) can generally be derived from any monomer that is polymerizable by addition or alkene insertion polymerization, for example, a monomer comprising a carbon-carbon double bond. In an aspect, the additional repeating units can be derived from ethylene, an alpha olefin (for example a C₂₋₁₀ alpha olefin), an acrylate, an acrylamide, a methacrylate, a methacrylamide, acrylonitrile, a vinyl monomer (e.g., N-vinylpyrrolidone), a styrenic monomer, or a combination thereof. In an aspect, the electroactive polymer can comprise additional repeating units derived from ethylene. In an aspect, the electroactive polymer can comprise additional repeating units derived from an acrylate. In an aspect, the additional repeating units can be derived from a cyclic olefin that does not comprise an electroactive species. In a specific aspect, the additional repeating units can be derived from a norbornene monomer, for example a norbornene carboxylic acid (C₁₋₆ alkyl) ester, for example 5-norbornene-2-carboxylic acid methyl ester.

The additional repeating units can preferably be selected to impart a desired property or functionality to the electroactive polymer. For example, one or more additional repeating units can comprise a crosslinkable group, an adhesion promoting group, a solubilizing group, a charged group, or a combination thereof.

Crosslinkable groups can include functional groups which are triggered by heat, radiation, or a chemical trigger suitable for forming a crosslinked network comprising the electroactive polymer. In an aspect, the crosslinkable group can generally be any functional group capable of participating in a chemical reaction with a complementary functional group. In an aspect, the crosslinkable group can comprise a nonspecific crosslinkable group. As used herein the term “nonspecific crosslinkable group” refers to a crosslinking moiety that does not require the presence of a complementary functional group. Rather, the nonspecific crosslinkable group is capable of activation to provide a highly reactive group such as a carbene, which can form crosslinks nonspecifically. Crosslinks formed from the crosslinkable groups can include ionic bonds, covalent bonds, or a combination thereof. When a nonspecific crosslinkable group is present, the crosslinks formed can be covalent bonds. Examples of the crosslinkable functional groups can include, but are not limited to, diazo groups, diazonium groups, silyl groups, alkynyl groups, vinyl groups, azido groups, epoxy groups, hydroxy groups, carboxy groups, amino groups, isocyanato groups, aluminum salts groups, halides (e.g., benzyl halides), or any combination thereof.

For example, the electroactive polymer can optionally further comprise crosslinkable repeating units according to Formulas (VIII) to (X), or a combination thereof

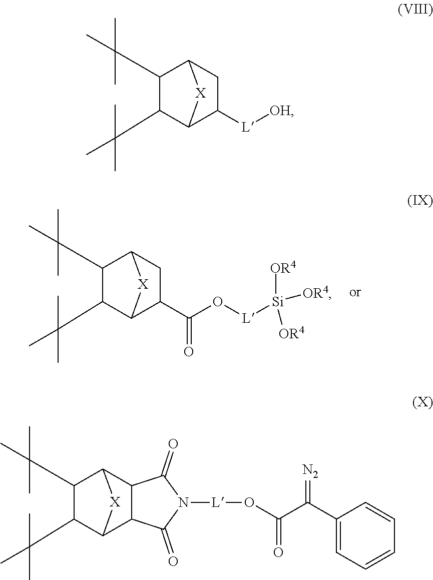

wherein X is —CH₂— or —O—, L′ is a C₁₋₁₂ alkylene linking group, a C₂₋₆ alkylene glycol linking group, or a poly(C₂₋₆ alkylene glycol) linking group, and R⁴ is independently at each occurrence a C₁₋₆ alkyl group. In an aspect, in Formula (VIII), X can be —CH₂— and L′ can be a methylene group. In an aspect, in Formula (IX), X can be —CH₂—, L′ can be a propylene group, and each occurrence of R⁴ can be a methyl group. In an aspect, in Formula (X), X can be —CH₂— and L′ can be an ethylene group. In an aspect, L′ can be an ethylene glycol group, a diethylene glycol group, or a poly(ethylene glycol) group.

As used herein “adhesion promoting groups” refer to a functional group which can increase interaction between the electroactive polymer and a substrate. For example, if the electroactive polymer is to be disposed on a carbonaceous substrate, it can be desirable to include groups which can interact with said carbonaceous materials, such as a polycyclic aromatic hydrocarbon group (e.g., pyrene). For example, the electroactive polymer can optionally further comprise repeating units according to Formula (XI)

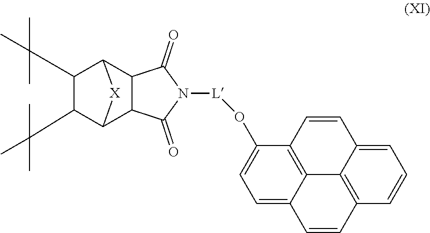

wherein X is —CH₂— or —O— and L′ is a C₁₋₁₂ alkylene linking group, a C₂₋₆ alkylene glycol linking group, or a poly(C₂₋₆ alkylene glycol) linking group. In an aspect, X is —CH₂— and L′ is an ethylene group.

Solubilizing groups as used herein refer to repeating units designed to increase the solubility of the electroactive polymer in a selected solvent. For example, suitable solubilizing groups can include C₁₋₂₀ alkyl groups or a poly(C₁₋₃₀ alkylene oxide) group (e.g., polyethylene glycol). Solubilizing C₁₋₂₀ alkyl groups can include linear and branched C₁₋₂₀ alkyl groups.

Charged groups as used herein refer to repeating units bearing a net positive or net negative charge. For example, the electroactive polymer can optionally comprise repeating units according to Formulas (XII) or (XIII)

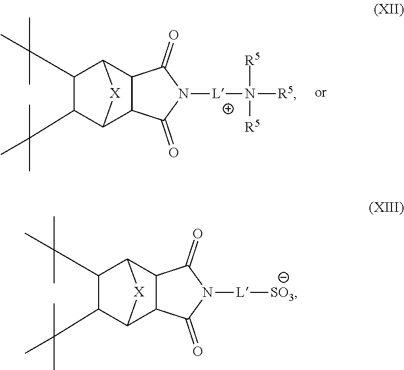

wherein X is —CH₂— or —O—, L″ is a C₁₋₁₂ alkylene linking group, a C₂₋₆ alkylene glycol linking group, or a poly(C₂₋₆ alkylene glycol) linking group, and R⁵ is independently at each occurrence a C₁₋₆ alkyl group. In an aspect, in Formula (XII), X is —CH₂—, L is an ethylene group, and each occurrence of R⁵ is a methyl group. In an aspect, in Formula (XIII), X is —CH₂— and L′ is a propylene group.

The electroactive polymer can have a number average molecular weight of 1,000 to 1,000,000 grams per mole. Within this range, the electroactive polymer can have a number average molecular weight of 1,000 to 750,000 grams per mole, or 1,000 to 500,000 grams per mole, or 1,000 to 250,000 grams per mole, 1,000 to 200,000 grams per mole, or 10,000 to 200,000 grams per mole, preferably 10,000 to 100,000 grams per mole, more preferably 10,000 to 75,000 grams per mole, even more preferably 20,000 to 50,000 grams per mole. In an aspect, the electroactive polymer can have a number average molecular weight of 1,000 to 50,000 grams per mole, or 1,000 to 25,000 grams per mole, or 1,000 to 10,000 grams per mole. Molecular weight can be determined, for example, using gel permeation chromatography (GPC) in tetrahydrofuran relative to polystyrene standards.

Methods for the manufacture of the electroactive polymer of Formula (I) represent another aspect of the present disclosure. The method comprises polymerizing an electroactive monomer of Formula (XIV)

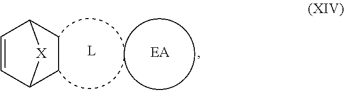

under conditions effective to provide the electroactive polymer comprising repeating units of Formula (I). In Formula (XIV), X, L, and EA can be as described above.

In an aspect, the electroactive polymers can be prepared by addition polymerization under conditions effective to provide the polymer according to Formula (I). For example, free radical polymerization can be used to provide the polymers according to Formula (I). The polymerizing can be conducted in the presence of a free radical initiator. Exemplary free radical initiators can include persulfates (e.g., potassium persulfate, ammonium persulfate, sodium persulfate), azo-containing moieties (e.g., azobisisobutyronitrile and dimethyl azoisobutyrate), and peroxides (e.g., benzyl peroxide, t-butyl peroxide, diisopropylbenzene hydroperoxide and t-butyl hydroperoxide). Reaction conditions including reaction temperature can be selected based on the initiator selected, for example, based on the thermal degradation temperature of the initiator when a thermal initiator is employed. Controlled free radical processes are also contemplated.

In an aspect, the electroactive polymers can be prepared by alkene insertion polymerization under conditions effective to provide the polymer according to Formula (I). For example, the electroactive polymers can be prepared by alkene insertion polymerization in the presence of a palladium or nickel catalyst. Exemplary palladium or nickel catalysts can include, for example, those described in Chem. Commun., 2010, 46, 7879-7893 and CoordChemRev 2009, 253, 827-861, the contents of each of which are incorporated herein by reference in their entirety. Catalysts can optionally be generated insitu.

In an aspect, the catalyst can be a palladium catalyst. Exemplary palladium catalysts can include, but are not limited to, Pd(ACN)₄(BF₄)₂, [PdCl(allyl)]₂+AgSbF₆, or a catalyst of the structure

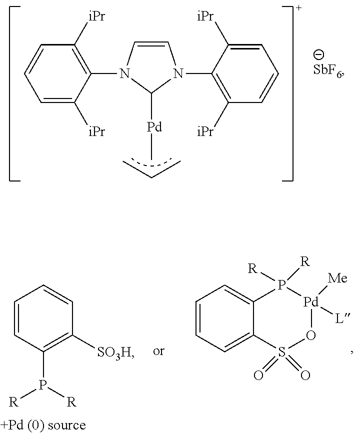

wherein in the foregoing structures, R is phenyl, o-methoxyphenyl, or cyclohexyl, and L″ is dimethyl sulfoxide, pyridine, or lutidine.

The foregoing polymerizations to provide the electroactive polymer according to Formula (I) can be carried out in the presence of an organic solvent such as toluene, chloroform, chlorobenzene, xylene, or a combination thereof. A suitable solvent can be selected based on the solubility of the various components of the reaction. The foregoing polymerizations are typically conducted under inert conditions, for example in the absence of moisture or air. It is noted that certain catalysts may tolerate the presence of air or water and thus inert conditions may not be required. The skilled person, guided by the present disclosure, understands how to select suitable polymerization conditions based on the polymerization methodology selected.

In an aspect, the conditions effective to provide the electroactive polymer comprise a time of 1 to 72 hours and a temperature of 15° C. or more, or 20° C. or more, or 40° C. or more, for example 20 to 100° C., or 40 to 100° C.

The method can optionally further comprise quenching the polymerization, for example using a reagent capable of cleaving the catalyst from the polymer chain to discontinue propagation. An exemplary quenching agent can include triethyl silane.

The electroactive polymers can be recovered from the reaction mixture, for example by combining the reaction mixture with a suitable non-solvent to precipitate the electroactive polymer product. Exemplary non-solvents can include, but are not limited to, methanol, methanolic hydrochloric acid, and diethyl ether. Methanolic hydrochloric acid can refer to a solution of concentrated hydrochloric acid in methanol, for example at a hydrochloric acid concentration of 0.1 to 10 volume percent, or 0.1 to 5 volume percent, or 0.5 to 5 volume percent, or 0.5 to 3 volume percent. The electroactive polymer product can be isolated using a solid-liquid separation technique, for example filtration or centrifugation.

In an aspect, the polymerization can be conducted in a solvent which can be useful for subsequent formulation steps, which can be determined based on the desired application. Accordingly, in an aspect, the electroactive polymer can be used without further purification or isolation from the polymerization reaction mixture.

In an aspect, the electroactive polymer can be purified to remove residual metal catalyst, for example by passing the polymerization solution through a column of adsorbent such as silica or alumina. The purified polymerization mixture can optionally be further used for subsequent formulation steps without isolating the electroactive polymer from the solvent. Alternatively, the purified polymerization mixture can be isolated as described above, for example by precipitation and filtration. Alternatively, the purified polymerization mixture can be exchanged into another solvent, for example a less volatile solvent, without precipitating the polymer.

Polymer products can be characterized by nuclear magnetic resonance (NMR) spectroscopy, ultraviolet (UV)-visible spectroscopy, infrared (IR) spectroscopy, or gel permeation chromatography (GPC). Electrochemical characterization of polymer products can include solution-phase or solid-phase electrochemical techniques such as cyclic voltammetry (CV).

The electroactive polymers of the present disclosure can be particularly useful for a variety of electrochemical applications. For examples, the electroactive polymers described herein can be useful for energy storage, electrochromic applications, catalysis, and gas separation.

A composite comprising the electroactive polymer represents another aspect of the present disclosure. The composite can comprise the electroactive polymer as described above disposed on a substrate.

The electroactive polymer can be disposed on at least a portion of a surface of the substrate. In an aspect, the substrate can be impregnated with the electroactive polymer. In an aspect, one or more intervening layers can be positioned between the substrate and the electroactive polymer. In an aspect, no intervening layers are present and the electroactive polymer can be disposed directly on a surface of the substrate. In an aspect, the substrate can comprise a carbonaceous material. Exemplary carbonaceous materials can include, but are not limited to, carbon paper (treated, TEFLON-treated, or untreated), carbon cloth, nonwoven carbon mat, or a nonwoven carbon nanotube mat. In an aspect the substrate can comprise a nonwoven carbon nanotube mat, for example as described in co-pending International Application No. PCT/US2021/049751, the contents of which are incorporated by reference in their entirety for all purposes. In an aspect, the substrate can comprise vertically aligned carbon nanotubes, for example as described in co-pending International Application No. PCT/US2021/059048, the contents of which are incorporated by reference in their entirety for all purposes.

The electroactive polymer can be referred to as being immobilized on the substrate such that the electroactive polymer is not capable of freely diffusing away from or dissociating from the substrate. The electroactive polymer can be immobilized on the substrate in a variety of ways. For example, the electroactive polymer can be immobilized on the substrate by being bound (e.g., via covalent bonds, ionic bonds, or intramolecular interaction such as electrostatic forces, van der Waals forces, hydrogen bonding, or a combination thereof) to the surface of the substrate. In an aspect, the electroactive polymer can be immobilized on the substrate by being adsorbed onto a surface of the substrate. In an aspect, the electroactive polymer can be immobilized on the substrate. Immobilizing the electroactive polymer can include, but is not limited to, grafting or polymerizing the electroactive polymer onto a surface of the substrate. “Grafting” as used herein refers to a chemical or electrochemical process producing a covalent bond between the electroactive polymer and the substrate. In an aspect, the electroactive polymer can be immobilized on the substrate by being included in a composition, e.g., a coating or a composite layer that is applied or deposited onto the substrate. Immobilizing the electroactive polymer can also include electrodeposition, plasma deposition, vacuum infiltration, melt coating, or a combination of any of the foregoing.

The thickness of the electroactive polymer on the surface of the substrate can be, for example, 0.1 to 20 nanometers, or 0.2 to 15 nanometers, or 0.5 to 10 nanometers. The thickness of the electroactive polymer on the surface of the substrate can depend on the mode of deposition.

The composite can optionally be porous. For example, the composite can have a porosity of at least 10%, or at least 20%, or at least 30%, for example 10 to 60%, or 20 to 60%, or 30 to 60%, each based on a total volume of the composite.

The composite can comprise the electroactive polymer in an amount of 1 to 90 weight percent, based on the total weight of the composite. Within this range, the electroactive polymer can be present in an amount of at least 2 weight percent, or at least 5 weight percent, or at least 7 weight percent, or least 10 weight percent, at least 20 weight percent, or at least 25 weight percent, or at least 30 weight percent, or least 40 weight percent, or at least 50 weight percent, based on the total weight of the composite. Also within this range, the electroactive polymer can be present in an amount of at most 85 weight percent, or at most 80 weight percent, or at most 70 weight percent, or at most 60 weight percent, or at most 50 weight percent, or at most 45 weight percent, or at most 40 weight percent. For example, the electroactive polymer can be present in an amount of 1 to 75 weight percent, or 5 to 60 weight percent, or 7 to 25 weight percent, based on the total weight of the composite.

An electrode assembly represents another aspect of the present disclosure. In an aspect, the electrode assembly comprises the composite as described above and a porous separator. The composite can be disposed on the porous separator, optionally with one or more intervening layers disposed between the composite and the porous separator. In an aspect the composite can be laminated to the porous separator. The porous separator can comprise any suitable material. In an aspect, the porous separator can comprise a polymer film, for example a film comprising a polyamide, a polyolefin, a polyaramid, a polyester, a polyurethane, an acrylic resin, and the like, or a combination thereof. The polymer may be coated on one or both sides with ceramic nanoparticles. In an aspect, the porous separator can comprise cellulose, a synthetic polymeric material, or a polymer/ceramic composite material. Further examples of separators can include polyvinylidene difluoride (PVDF) separators, polytetrafluoroethylene (PTFE), PVDF-alumina composite separators, and the like.

In an aspect, the electrode assembly can comprise a patterned electrode, for example as described in co-pending U.S. application Ser. No. 17/345,074, the contents of which is incorporated by reference in its entirety for all purposes.

An electrochemical cell comprising the electroactive polymer represents another aspect of the present disclosure. For example, the electrochemical cell can comprise a first electrode, a second electrode, a separator between the first electrode and the second electrode, and an electrolyte. The electroactive polymer of the present disclosure can be present in the electrochemical cell in at least one of the first electrode, the second electrode, or the electrolyte. In an aspect, a plurality of electrochemical cells can comprise the electroactive polymer, where the electrochemical cells are in electronic communication, for example in parallel or in series, or any suitable combination of parallel and series.

In an aspect, an electrochemical cell can comprise the composite comprising the electroactive polymer. For example, the electrochemical cell can comprise a first electrode comprising the above-described composite comprising the electroactive polymer, a second electrode comprising a complementary electroactive composite layer, and a first separator between the first electrode and the second electrode.

The separator can be as described above for the electrode assembly. The separator can serve as a protective layer that can prevent the respective electrochemical reactions at each electrode from interfering with each other. The separator can also help electronically isolate the first and second electrodes from one another or from other components within the electrochemical cell to prevent a short-circuit. A person of ordinary skill, with the benefit of this disclosure, would be able to select a suitable separator. A microporous polyolefin separator is mentioned.

The electrochemical cell can further comprise an electrolyte. The electrolyte can have a suitable conductivity at room temperature (e.g., 23° C.). In an aspect the separator can be partially or completely impregnated with the electrolyte. Impregnating the separator with the electrolyte can be by submerging, coating, dipping, or otherwise contacting the separator with the electrolyte. Some or all of the pores of the porous separator can be partially or completely filled with the electrolyte. In an aspect, the separator can be saturated with the electrolyte.

In an aspect the electrolyte comprises an ionic liquid, for example a room temperature ionic liquid (RTIL). Ionic liquids can have low volatility, for example a vapor pressure of less than 10⁻⁵ Pascals (Pa), or 10⁻¹⁰ to 10⁻⁵ Pa at a temperature of 23° C. The low volatility can reduce the risk of the separator drying out and allow for reduction in loss of the electrolyte due to evaporation or entrainment. In an aspect, the ionic liquid accounts for substantially all (e.g., at least 80 volume percent, or at least 90 volume percent, or at least 95 volume percent, or at least 98 volume percent, at least 99 volume percent, or at least 99.9 volume percent) of the electrolyte.

The ionic liquid comprises an anion component and a cation component. The anion of the ionic liquid can comprise, but is not limited to halide, sulfate, sulfonate, carbonate, bicarbonate, phosphate, nitrate, nitrate, acetate, hexafluorophosphate (PF₆⁻), tetrafluoroborate (BF₄⁻), triflate, nonaflate, bis(trifluoromethylsulfonyl)amide, trifluoroacetate, heptafluorobutanoate, haloaluminate, triazolide, or an amino acid derivative (e.g., proline with the proton on the nitrogen removed). The cation of the ionic liquid can comprise one or more of, but is not limited to, imidazolium, pyridinium, pyrrolidinium, phosphonium, ammonium, sulfonium, thiazolium, pyrazolium, piperidinium, triazolium, pyrazolium, oxazolium, guanadinium, an alkali cation, or dialkylmorpholinium. In an aspect, the room temperature ionic liquid comprises an imidazolium as a cation component. In an aspect, the room temperature ionic liquid comprises 1-butyl-3-methylimidazolium (“Bmim”) as a cation component. In an aspect, the room temperature ionic liquid comprises bis(trifluoromethylsulfonyl)imide (“TFSI”) as an anion component. In an aspect, the room temperature ionic liquid comprises 1-butyl-3-methylimidazolium bis(trifluoromethylsulfonyl)imide (“[Bmim][TFSI]”). In an aspect, the room temperature ionic liquid comprises 1-butyl-3-methylimidazolium tetrafluoroborate (“BF₄”) (“[Bmim][BF₄]”).

In an aspect the electrochemical cell of the present disclosure can comprise a first electrode, a second electrode, a separator disposed between the electrodes, and an electrolyte as disclosed above, wherein the electroactive polymer of the present disclosure can be dissolved in the electrolyte.

The second electrode of the electrochemical cell comprises a complementary electroactive composite layer. The complementary electroactive composite layer can be the same or different from the composite comprising the electroactive polymer of the present disclosure. The complementary electroactive composite layer comprises an electroactive species which can be the same or different as the electroactive polymer of the composite of the first electrode.

In an aspect, the complementary electroactive composite layer comprises the same electroactive polymer as the composite of the first electrode. In an aspect, the complementary electroactive composite layer comprises an electroactive species which is different from the electroactive polymer of the composite of the first electrode (“a second electroactive species”). The second electroactive species can serve as a source of electrons for the reduction of the first electroactive species present in the first electrode. Likewise, the second electroactive species may serve as a sink for electrons during oxidation of the first electroactive species. The second electroactive species can comprise, for example, polyvinyl ferrocene, poly(3-(4-fluorophenyl)thiophene), or other Faradaic redox species with a reduction potential at least 0.1, or at least 0.15 volts more positive than that of the first reduction potential of the first electroactive species (e.g., the electroactive polymer of the present disclosure).

In an aspect, the second electrode can further comprise a substrate, which can be positioned proximate to or between complementary electroactive composite layers. The substrate can be in direct or indirect contact with the complementary electroactive composite layer or layers. When present, the substrate can include, for example, carbon paper (treated, TEFLON-treated, or untreated), carbon cloth, nonwoven carbon mat, or a nonwoven carbon nanotube mat. In an aspect, the support can comprise the same carbonaceous material of the composite of the first electrode. In an aspect, the substrate of the second electrode can be a conductive material and act as a current collector within the electrochemical cell.

In an aspect, the first electrode can be a negative electrode, and the second electrode can be a positive electrode. The terms negative electrode and positive electrode are used for convenience and clarity, although they may be technically accurate only when the target gas is being acquired or released.

In an aspect, the second electrode can be positioned between first electrodes. Each of the first electrodes can comprise the disclosed composite. In an aspect the first electrodes and/or second electrodes can be identical in configuration or composition.

In an aspect, the electrochemical cell comprises a single separator, disposed between the first electrode and the second electrode, e.g., between the negative electrode and the positive electrode. The separator can serve as a protective layer that can prevent the respective electrochemical reactions at each electrode from interfering with each other. The separator can also help electronically isolate the first and second electrodes from one another or from other components within the electro-swing adsorption cell to prevent a short-circuit. A person of ordinary skill, with the benefit of this disclosure, would be able to select a suitable separator.

In an aspect, the electrochemical cell comprises a single separator, disposed between the first electrode and the second electrode, e.g., between the negative electrode and the positive electrode. Electrochemical cells can be combined to make a stack in any suitable combination of parallel and series configurations. In an aspect, the electrochemical cell can comprise more than one separator. For example, one of skill in the art would understand that depending on the selected combination of series and parallel configurations, a single separator may be used, or a plurality of separators may be preferred.

The separator can be a porous separator. The porous separator can comprise any suitable material. In an aspect, the porous separator can comprise a polymer film, for example a film comprising a polyamide, a polyolefin, a polyaramid, a polyester, a polyurethane, an acrylic resin, or a combination thereof. The polymer may be coated on one or both sides with a ceramic nanoparticle. In an aspect, the porous separator can comprise cellulose, a synthetic polymeric material, or a polymer/ceramic composite material. Further examples of separators can include polyvinylidene difluoride (PVDF) separators, polytetrafluoroethylene (PTFE), PVDF-alumina composite separators, or a microporous olefin, such as a microporous polyethylene or microporous polypropylene.

The electrochemical cell can further comprise a current collector which conducts electrons from the electrode to the adjacent cell (in series-stacked configurations) or from the electrode to a terminal connection (in parallel-stacked configurations). The current collector can comprise, for example, carbon, a metal, or a combination thereof. In an aspect, the current collector can comprise carbon. Suitable examples of the carbon can include, but are not limited to, graphite, flaked graphite, expanded graphite, carbon fiber, carbon nanotubes, amorphous carbon, graphene, or a combination thereof. The carbon nanotubes may comprise single-wall carbon nanotubes or multi-wall carbon nanotubes. Carbon nanotubes are primarily carbon, although the nanotube fiber may further comprise other atoms, such as boron, nitrogen, or one or more of various metals. In an aspect, the current collector can comprise a metal. The metal can comprise Fe, Zn, Ti, Cu, Al, Ni, Mg, Sn, Cr, Mn, Au, Mo, W, In, V, Nb, Ag, an alloy or intermetallic thereof, or a combination thereof. In an aspect the alloy is a stainless steel, such as 304 or 316 stainless steel.

In an aspect, the carbon or metal may have a spherical, flake, or fibrous morphology. In an aspect, the metal may be in the form of a metal mesh, foam, felt, or an expanded metal. The carbon or metal particles can be oriented. For example, when the metal is in the form of a fiber, the fibers can be oriented such that a long axis is oriented in a direction perpendicular to a major surface of the current collector, e.g., such that the fiber is oriented orthogonal to the surface, e.g., in a through-plane direction.

In an aspect, the current collector can comprise a composite comprising the carbon, the metal, and a binder. The carbon or metal in the composite can be present in an amount of 10 to 98 vol %, based on the total volume of the composite. In an aspect, the composite comprises the carbon or the metal in an amount of 50 to 95 vol %, based on the total volume of the composite. In an aspect, the composite comprises carbon nanotubes or graphene and can include the carbon nanotubes or graphene in an amount of 10 to 40 vol %, based on the total volume of the composite. The composite may comprise a pore, and the pore may contain a polymer.

The binder, when present, can comprise a polymer. The binder can be a thermoset or a thermoplastic. Suitable polymer binders can include, for example, an epoxy, a phenolic, a vinyl ester, a polyarylene sulfide, a polybenzoxazine, an isocyanate, a fluoropolymer, a rubber, or a combination thereof. Representative polymer binders can include polyacrylic acid (PAA), polyvinylidene difluoride, polyvinyl alcohol, carboxymethyl cellulose (CMC), starch, hydroxypropyl cellulose, regenerated cellulose, polyvinylpyrrolidone, tetrafluoroethylene, polyethylene, polypropylene, ethylene-propylene-diene monomer (EPDM), sulfonated EPDM, styrene-butadiene-rubber, or a fluorinated rubber. A combination comprising one of the foregoing polymer binders may be used.

The binder can optionally further include an additive. Specific additives can include flow promoters, mold release agents, or a combination thereof. In an aspect, the polymer binder can be crosslinked. The polymer can be an electrical insulator or an electrical conductor. An exemplary electrically conducting polymer can be found, for example, in U.S. Patent Publication No. 2005/0109990, the contents of which are incorporated by reference herein in its entirety for all purposes. Optionally, a conductive material such as carbon black, nanotubes, carbon fiber, graphene, and the like can be embedded in the polymer binder at a surface of the current collector, which, without wishing to be bound by theory, is believed to reduce the contact resistance to an adjacent cell component such as to the gas diffusion layer.

In an aspect, the current collector can optionally comprise a coating disposed on at least a portion of a surface of the current collector. The coating can, without wishing to be bound by theory, serve to reduce corrosion, block ion or gas permeation, or improve electrical contact to the gas-diffusion layer or electrode. The coating, when present, can comprise carbon, a metal, an alloy, or an intermetallic material, or a combination thereof, wherein the metal, alloy, or intermetallic material comprises Ni, Zn, Ti, Sn, Au, V, Mo, Cr, or a combination thereof. The coating can comprise an oxide, boride, nitride, or carbide of a metal, alloy, or intermetallic. Non-limiting examples of coating compositions can include tin oxide, titanium carbide, tungsten carbide, zirconium carbide, indium tin oxide, indium zinc oxide, titanium boride, zirconium boride, titanium niobium oxide, titanium tantalum oxide, lanthanum strontium chromium oxide, lanthanum strontium cobalt oxide, titanium nitride, chromium nitride, vanadium nitride, or a combination thereof. For example, in an aspect, the current collector can be plated with a metal, such as Fe, Ni, or Au, or a corrosion-resistant material such as TiN. In an aspect, the coating can comprise a polymer. An example of a polymer coating is described, for example, in U.S. Patent Publication No. 2007/0298267, the contents of which are incorporated by reference herein in their entirety for all purposes. In an aspect, the coating can comprise an electrically conducting polymer. In an aspect, the coating can comprise the binder as described above, and particles of a conductive material, such as carbon black, carbon nanotubes, graphene, gold, silver, or a combination thereof. In an aspect, the coating comprises vapor-deposited diamond-like carbon, or a product of pyrolysis of a carbonaceous polymer.

The current collector may have any suitable porosity, and in an aspect is nonporous. In an aspect, the current collector is effectively impervious to a target gas, e.g., carbon dioxide.

The electrochemical cell may be stacked in series, and the current collector may block transport of ions and of reactant and released gas from a first cell to a second neighboring cell. Furthermore, the current collector can impart mechanical structure and stability to an electrochemical cell. The current collector can optionally comprise ribs which form channels which provide a flowfield for distribution of the gas across the cell. The rib may conduct electrons across the electrochemical cell and optionally provide desirable structural integrity. The rib, when present, can comprise, for example, carbon, a metal, a composite, or a combination thereof, as disclosed above, and can optionally include the coating, each of which is further described above. The rib may comprise the same material as the current collector. The rib may comprise a different material from the current collector. The rib may comprise a material which can be partially compressed, in order to accommodate manufacturing thickness tolerances. For example, the rib may comprise an electronically-conductive closed-cell foam or gasket. The ribs may be convex or concave portions relative to the surface of the current collector and can have any suitable cross-sectional shape, for example a rectangular or rounded shape.

In an aspect, a first side of the current collector can face an adsorbent electrode (e.g., the first electrode), and a second, opposite side of the current collector faces a non-adsorbent counter electrode (e.g., the second electrode) or an end plate. In an aspect, both sides of the current collector can face adsorbent electrodes. The side of the current collector which faces an adsorbent electrode may comprise a flow field. The sides of the current collector, e.g., the first side and the second side, can each independently comprise the same or a different material. In an aspect, an intervening layer comprising a barrier material, such as a material which is electrically conductive and can block the transport of ions or gas, can be interposed between the first and second sides of the current collector. In an aspect, the barrier material can comprise a metal foil.

The current collector can include a feature to aid with sealing the perimeter of the apparatus. Such features can include grooves, steps, bevels, or a combination thereof. Such features are described, for example, in U.S. Patent Publication No. 2002/0197519, the contents of which are incorporated by reference herein in their entirety for all purposes.

The current collector can further comprise a channel extending through the interior of the current collector, preferably through which coolant can flow. The coolant channel can be arranged so that the coolant flow rate is highest in the region of the cell expected to have the highest rate of heat generation, as can be readily determined by one of ordinary skill in the art. Use of a parallel or serpentine configuration is mentioned. In an aspect in which a foam or mesh, such as an electrically conductive foam or mesh, is used, the coolant can flow through the foam or mesh. The foam or mesh may be provided between two layers of the current collector. In an aspect, the coolant can flow through a corrugated or waveform structure, provided between opposite layers of the current collector.

In an aspect, the current collector can comprise a first sheet that contains a channel for reactant gas flow on a first face, and a channel for coolant on a second, opposite face. The first sheet can be attached to a second sheet, which forms a boundary for the coolant channels while providing electrical conduction orthogonal to the face of the sheets. The first sheet can be attached to the second sheet by any suitable method, for example, brazing, welding, soldering, laminating, diffusion bonding, compression, or adhesive bonding. The coolant channels can be formed by nesting adjacent plates, which contain flow-fields for the first and second electrodes. Coolant channels are described in U.S. Pat. No. 6,099,984, and further exemplary coolant flow patterns can be found in provided in U.S. Patent Publication Nos. 2004/0209150 and 2003/0203260, the contents of each of which are incorporated by reference herein in their entirety for all purposes.

The current collector can further comprise a sensor, e.g., a voltage sensor or a voltage sensing wire connected to the current collector. In an aspect, the current collector can further comprise a heating element.

In an aspect, the current collector can comprise members to facilitate assembly, such as alignment pins. Alternatively, a frame may be provided at a periphery of the current collector to aid alignment or sealing. Examples of various suitable current collector components can be found in U.S. Patent Publication No. 2003/0022052, the contents of which are incorporated by reference herein in their entirety for all purposes.

The electrochemical cell can optionally further comprise a gas flow field. The gas flow field, when present, can be positioned between the first electrode and the current collector. When the gas diffusion layer is not present in the electrochemical cell, the gas flow field can be positioned adjacent to the first electrode, on a side opposite the separator. In an aspect, the gas flow field can be positioned adjacent to a current collector or a side of the current collector may comprise a flow field. The flow field can comprise structures for directing the reacting fluid to flow from a flow inlet to a flow outlet. Without wishing to be bound by theory, the flow field serves to provide uniform reactant flow to the electrode area. Preferably, the flow field provides uniform reactant flow to the electrode area, a low barrier to flow e.g., a low pressure drop, and suitable electrical conduction from the electrode through the flow field to the current collector.

The gas flow field can optionally further comprise a gas diffusion layer. The gas diffusion layer can be positioned adjacent to the first electrode, on a side opposite the separator. The gas diffusion layer can comprise a porous, electrically conductive material. In an aspect, the gas diffusion layer has a porosity, for example, of greater than or equal to 60%, greater than or equal to 70%, greater than or equal to the 75%, greater than or equal to 80%, or greater. In an aspect, the gas diffusion layer has a porosity of less than or equal to 85%, less than or equal to 90%, or more, based on a total volume of the gas diffusion layer. Combinations of these ranges are possible. For example, in an aspect, the gas diffusion layer of the first electrode has a porosity of greater than or equal to 60% and less than or equal to 90%. Other porosities are also possible. Examples of suitable materials for the gas diffusion layer include, without limitation, carbon paper (treated, PTFE-treated, or untreated), carbon cloth, or a nonwoven carbon fiber or carbon nanotube mat.

In an aspect, the flow field can comprise a porous foam or mesh. The foam or mesh can be bonded to a nonporous plate by a conductive adhesive, welding, heat-bonding, or sintering.

The flow field can comprise a channel. The channel can be defined by two or more ribs. In an aspect, the channels, the ribs, or both can each independently have average widths of at least 0.1 millimeter (mm), at least 0.2 mm, at least 0.3 mm, at least 0.4 mm, at least 0.5 mm, at least 0.6 mm, at least 0.8 mm, at least 0.9 mm, at least 1 mm, at least 2 mm, at least 3 mm, at least 4 mm, at least 5 mm, at least 6 mm, at least 7 mm, at least 8 mm, or at least 9 mm. In an aspect, the channels, the ribs, or both can each independently have average widths of no more than 10 mm, no more than 9 mm, no more than 8 mm, no more than 7 mm, no more than 6 mm, no more than 5 mm, no more than 4 mm, no more than 3 mm, no more than 2 mm, no more than 1 mm, no more than 0.9 mm, no more than 0.8 mm, no more than 0.7 mm, no more than 0.6 mm, no more than 0.5 mm, no more than 0.4 mm, no more than 0.3 mm, or no more than 0.2 mm. Combinations of the above-referenced average widths for the channels and/or the ribs are also possible.

In an aspect, the channels, the ribs, or both can each independently have average depths of at least 0.1 mm, at least 0.2 mm, at least 0.3 mm, at least 0.4 mm, at least 0.5 mm, at least 0.6 mm, at least 0.8 mm, at least 0.9 mm, at least 1 mm, at least 2 mm, or at least 3 mm. In an aspect, the channels, the ribs, or both can each independently have average depths of no more than 4 mm, no more than 3 mm, no more than 2 mm, no more than 1 mm, no more than 0.9 mm, no more than 0.8 mm, no more than 0.7 mm, no more than 0.6 mm, no more than 0.5 mm, no more than 0.4 mm, no more than 0.3 mm, or no more than 0.2 mm. Combinations of the above-referenced average depths for the channels and/or the ribs are also possible.

Various methods for manufacturing a flow field may be used, e.g., machining, injection molding, compression molding, extruding, embossing, or stamping. Exemplary methods are described, for example, in U.S. Publication No. 2004/0151975 and U.S. Publication No. 2003/0022052, the contents of each of which are incorporated by reference herein in their entirety for all purposes. In an aspect, the flow field can comprise a corrugated metal with couplings to route the flow from one channel to a neighboring channel, for example as described in U.S. Publication No. 2002/0081477, the contents of which are incorporated by reference herein in their entirety for all purposes.

A flow pattern of the flow field can have any suitable configuration, e.g., to provide parallel, serpentine, or interdigitated flow. Non-limiting examples of serpentine flow patterns are provided in U.S. Pat. No. 6,309,773, the contents of which are incorporated by reference herein in their entirety for all purposes. Flow channels can have a uniform cross-section or can have regions which are tapered or constricted, e.g., to provide a suitable distribution of reactant across the cell area. The flow channels may contain a disruption or obstacle, e.g., to generate turbulence which can improve transport of reactants into the electrode. Exemplary flow channels are described in U.S. Pat. No. 6,756,149, the contents of which are incorporated by reference herein in their entirety for all purposes. The flow field pattern and dimensions can be the same for each flow field in a cell, or they can vary depending on the position of the cell within the stack and the nature of the electrode facing the flow field, as can be readily determined by a skilled person. In an aspect, when channels on both faces of the current collector are present, the channels can be nested to reduce the thickness of the stack.

In an aspect, a manifold can be used to deliver a process gas, e.g., a reactant gas, to the electro-swing adsorption cell, and to convey a product gas, e.g., a released gas, away from the electro-swing adsorption cell. The manifold can distribute the gas. Parameters such as manifold length and cross-sectional dimensions can be selected to provide suitable properties, such as pressure drop. The manifold can also preferably prevent leakage of the gas. Exemplary manifold designs that can be used include but are not limited to those disclosed in U.S. Pat. Nos. 6,159,629; 6,174,616; 5,486,430; 5,776,625; and 6,017,648; the contents of each which are incorporated by reference herein in their entirety for all purposes.

In an aspect, the electrochemical cell can include a seal to prevent leakage of process gases out of the electro-swing adsorption cell. The surface facing the seal region, e.g., a surface of the gas-diffusion layers, electrodes, or separators, can be impregnated at their periphery with a gas-impermeable sealant. Preferably, the geometry of the seal is selected such that stress that can result in puncture, fatigue, or tearing of the separator is not introduced. The thickness of the seal can be uniform or can vary across different regions of the seal with respect to the edge of the electrode and the gas diffusion layer. The seal is electrically insulating and chemically and electrochemically unreactive. The seal can comprise a suitable o-ring, gasket, or adhesive. The seal can comprise a ridge or bead of fluid-impermeable material deposited on the periphery of a member, such as the current collector or manifold. In an aspect, the seal can comprise an elastomer, and can be a thermoset or a thermoplastic, for example, an epoxy, a rubber, a polyolefin, a silicone, a fluoropolymer, a fluoro-elastomer, or a chloropolymer. In an aspect, the seal can comprise a foam, for example a foamed rubber. In an aspect, the seal can comprise a heat-shrinkable film. Exemplary seal materials are described in U.S. Pat. No. 6,440,597 and U.S. Publication No. 2006/0073385, the contents of each of which are incorporated by reference herein in their entirety for all purposes.

In an aspect, when the seal is a gasket, the gasket can optionally comprise a filler, which preferably can provide a coefficient of thermal expansion of the gasket material that is matched to that of the adjacent material, e.g., the current collector material. Exemplary fillers can include, but are not limited to, glass, polystyrene, poly(tetrafluoroethylene) (PTFE), or an insulating metal oxide such as silica or alumina.

Suitable seals can be manufactured by any suitable method, e.g., injecting a bonding polymer into a groove around the edge of the cell, for example as described in U.S. Publication No. 2003/0031914, the contents of which are incorporated by reference herein in their entirety for all purposes. The method can comprise forming grooved surfaces with correspondingly shaped gaskets, for example as described in U.S. Publication No. 2003/0072988, the contents of which are incorporated by reference herein in their entirety for all purposes. In an aspect, the sealant material can be coated, sprayed, laminated, or injection molded onto the current collector or onto an assembly of the gas diffusion layer, electrodes, separator, or a combination thereof. The sealant can encapsulate the exterior-facing edges of the cell. Examples of seal geometries are described in U.S. Publication Nos. 2007/0231619, 2007/0042254, and 2002/0172852, and U.S. Pat. No. 6,261,711, the contents of each of which are incorporated by reference herein in their entirety for all purposes. In an aspect, a gasket on opposite sides of the separator can be connected to each other through through-holes optionally included in a peripheral region of the separator.

To improve sealing, in an aspect the separator can be nonporous in the periphery region. A method of rendering the separator nonporous comprises hot-pressing the separator at a temperature sufficient to cause the material (e.g., a polymeric material) of the separator to flow, thereby filling the pores. The separator can be hot-pressed or thermally bonded to a gasket or adhered with a sealant.

It can be advantageous to remove heat from the electrochemical cell to prevent the internal temperature from exceeding temperatures that can damage the electrochemical cell. Heat removal can be achieved through the use of coolant channels, discussed previously. In an aspect, the electrochemical cell can be cooled by blowing air over a side of the electrochemical cell. In an aspect, the electrochemical cell can be cooled by flowing coolant through tubes or ducts alongside a side or within the electrochemical cell. In an aspect, the current collector can be devoid of any coolant channels, and cooling can be provided by controlling the flow rate of a process gas through the electrochemical cell, effectively using the process gas as a coolant. This cooling method can be particularly advantageous if the process gas (reactant gas) is air.

In an aspect, at least a portion of the electrochemical cell can be heated. For example, an end portion of the electrochemical cell can be heated, or the cells at the ends of the electrochemical cell (e.g., the “end cells”) can be heated. Without wishing to be bound by theory, heating the electrochemical cell can enable higher capture rate or prevent water condensation from a humid process gas. Electrical-resistance heating elements can be incorporated or disposed adjacent to an end plate or a manifold, for example.

Applying pressure across an electrochemical cell can be advantageous to reduce contact resistance between components within the electrochemical cell e.g., contact resistance between the flow field and the gas diffusion layer. Application of pressure can also be advantageous to improve seal hermeticity. Pressure can be applied across an electrochemical cell, for example, using tie rods or external clamps. A tie rod can be internal or external to the seals and manifolds. It can be preferable to apply pressure uniformly, without localized regions of mechanical stress that can lead to mechanical failure. Those skilled in the art will be familiar with the design of washers, disc springs, coiled springs, belleville washers, nuts, clamps, frames, fasteners, collets, wedges, or pressure plates to apply uniform pressure and avoid stress concentration. Examples of compression assemblies are described in, for example, U.S. Pat. No. 6,190,793, the contents of which are incorporated by reference herein in their entirety for all purposes.

The electroactive polymer of the present disclosure can be reactive towards a target gas. The target gas can be an electrophilic molecule. In an aspect, the target gas is a Lewis acid gas or a Bronsted acid gas, preferably a Lewis acid gas. The target gas is capable of forming a complex or an adduct with the electroactive polymer when the electroactive polymer is in a reduced state, for example, by bonding to the electroactive polymer in its reduced state. The target gas can comprise carbon dioxide (CO₂), a sulfur oxide species such as sulfur dioxide (SO₂) or sulfur trioxide (SO₃), an organosulfate (R₂SO₄, where each R is independently hydrogen, C₁₋₁₂ alkyl, or C₆₋₂₀ aryl) such as dimethyl sulfate, a nitrogen oxide species such as nitrogen dioxide (NO₂) or nitrogen trioxide (NO₃), a phosphate ester (R₃PO₄, where each R is independently hydrogen, C₁₋₁₂ alkyl, or C₆₋₂₀ aryl) such as trimethyl phosphate, an ester (RCOOR′ where each R is independently hydrogen, C₁₋₁₂ alkyl, or C₆₋₂₀ aryl, and each R′ is independently C₁₋₁₂ alkyl or C₆₋₂₀ aryl) such as methyl formate or methyl acrylate, an aldehyde (RCHO, where each R is independently hydrogen, C₁₋₁₂ alkyl, or C₆₋₂₀ aryl) such as formaldehyde or acrolein, a ketone (R₂CO, where each R is independently hydrogen, C₁₋₁₂ alkyl, or C₆₋₂₀ aryl) such as acetone, an isocyanate (RNCO, where each R is independently hydrogen, C₁₋₁₂ alkyl, or C₆₋₂₀ aryl, and each R′ is independently C₁₋₁₂ alkyl or C₆₋₂₀ aryl) such as methyl isocyanate, isothiocyanate (RNCS, where each R is independently hydrogen, C₁₋₁₂ alkyl, or C₆₋₂₀ aryl, and each R′ is independently C₁₋₁₂ alkyl or C₆₋₂₀ aryl), a borane (BR₃, where each R is independently hydrogen, C₁₋₁₂ alkyl, or C₆₋₂₀ aryl) such as trimethyl borane, or a borate (R₃BO₃, where each R is independently hydrogen, C₁₋₁₂ alkyl, or C₆₋₂₀ aryl) such as trimethyl borate. The target gas can optionally comprise a combination of any of the foregoing target gas species.

In an aspect, the electroactive polymer in a reduced state can have a binding constant with a target gas (e.g., carbon dioxide) of at least 10¹ M⁻¹, preferably 10¹ to 10²⁰ M⁻¹, more preferably 10³ to 10²⁰. In an aspect, a binding constant with a target gas may be 10³ to 10²⁰ M⁻¹, 10⁵ to 10¹⁸ M⁻¹, or 10⁸ to 10¹⁵ M⁻¹.

As such, an electrochemical cell comprising the electroactive polymer can be particularly useful for the separation of a target gas from a gas mixture when the gas mixture is contacted with the electrochemical cell, and thus is particularly well suited for use in a gas separation system. The gas separation system can comprise a plurality of electrochemical cells in fluid communication with a gas inlet and a gas outlet. In an aspect, the gas separation system can further comprise a contactor unit in fluid contact with a gas mixture. In an aspect, the contactor unit can be in fluid communication with an electrolyte. The contactor unit can include, for example, a gas adsorber, a gas absorber, or a combination thereof.

The gas mixture, also referred to as the input gas, can be at least partially separated upon exposure to the electrochemical cell. The gas mixture can be, for example, ambient air (e.g., air from an ambient environment, such as outdoor air). In an aspect, the gas separation system can be used for direct air capture. The systems and methods described herein can be useful for removing a target gas such as carbon dioxide directly from ambient air (e.g., to reduce greenhouse gas levels), without the need for any pre-concentration step. Certain aspects of the present disclosure can make the systems and methods described herein particularly useful for direct air capture (e.g., an ability to bond with a target gas while being thermodynamically disfavored from reacting with major components of ambient air, such as oxygen).

In an aspect, the concentration of the target gas in the gas mixture is relatively low, for example when the gas mixture is ambient air. For example, the concentration of the target gas in the gas mixture prior to exposure to the electrochemical cell can be less than or equal to 500 ppm, or less than or equal to 450 ppm, or less than or equal to 400 ppm, or less than or equal to 350 ppm, or less than or equal to 300 ppm, or less than or equal to 200 ppm. In an aspect, the concentration of the target gas in the gas mixture can be as low as 100 ppm, or as low as 50 ppm, or as low as 10 ppm.

In an aspect, the gas mixture (e.g., input gas mixture) is ventilated air. The ventilated air can be air in an enclosed or at least partially enclosed place (e.g., air being circulated in an enclosed place). Examples of places in which the gas mixture (e.g., ventilated air) can be located include, but are not limited to sealed buildings, partially ventilated places, car cabins, inhabited submersibles, air crafts, and the like.

The concentration of target gas in the ventilated air can be higher than ambient air but lower than concentrations typical for industrial processes. In an aspect, the concentration of the target gas in the gas mixture prior to exposure to the electrochemical cell is less than or equal to 5,000 ppm, or less than or equal to 4,000 ppm, or less than or equal to 2,000 ppm, or less than or equal to 1,000 ppm. In an aspect, the concentration of the target gas in the gas mixture (e.g., when it is ventilated air/air in enclosed spaces) is as low as 1,000 ppm, or as low as 800 ppm, or as low as 500 ppm, or as low as 200 ppm, or as low as 100 ppm, or as low as 10 ppm.

In an aspect, the gas mixture comprises oxygen gas (02). In an aspect, the gas mixture has a relatively high concentration of oxygen gas (e.g., prior to exposure to the electrochemical cell). Certain aspects of the systems and methods described herein (e.g., the choice of particular electroactive species, methods of handling gases in the system, etc.) can contribute to an ability to capture target gases in gas mixtures in which oxygen gas is present without deleterious interference. In an aspect, oxygen gas is present in the gas mixture (e.g., prior to exposure to the electrochemical cell) at a concentration of greater than or equal to 0 volume percent, or greater than or equal to 0.1 volume percent, or greater than or equal to 1 volume percent, or greater than or equal to 2 volume percent, or greater than or equal to 5 volume percent, or greater than or equal to 10 volume percent, or greater than or equal to 20 volume percent, or greater than or equal to 50 volume percent, or greater than or equal to 75 volume percent, or greater than or equal to 90 volume percent, greater than or equal to 95 volume percent. In an aspect, oxygen gas is present in the gas mixture at a concentration of less than or equal to 99 volume percent, or less than or equal to 95 volume percent, or less than or equal to 90 volume percent, or less than or equal to 75 volume percent, or less than or equal to 50 volume percent, or less than or equal to 25 volume percent, or less than or equal to 21 volume percent, or less than or equal to 10 volume percent, or less than or equal to 5 volume percent, or less than or equal to 2 volume percent.

In an aspect, the gas mixture comprises water vapor. The gas mixture can comprise water vapor for example, because it is or comprises ambient air or ventilated air. In an aspect, the gas mixture (e.g., prior to exposure to the electrochemical cell) has a relatively high relative humidity. For example, in an aspect, the gas mixture can have a relative humidity of greater than or equal to 0%, or greater than or equal to 5%, or greater than or equal to 10%, or greater than or equal to 25%, or greater than or equal to 50%, or greater than or equal to 75%, or greater than or equal to 90% at at least one temperature in the range of −50 to 140° C. In an aspect, the gas mixture can have a relative humidity of less than or equal to 100%, or less than or equal to 95%, or less than or equal to 90%, or less than or equal to 75%, or less than or equal to 50%, or less than or equal to 25%, or less than or equal to 10% at at least one temperature in the range of −50 to 140° C.

The target gas can be separated from the gas mixture in the gas separation system by applying a potential difference across the electrochemical cells of the gas separation system. One of ordinary skill, with the benefit of this disclosure, would understand how to apply a potential across the electrochemical cell. For example, the potential can be applied by connecting the negative electrode and the positive electrode to a suitable power source capable of polarizing the negative and positive electrodes. In an aspect the power supply can be a DC voltage. Nonlimiting examples of a suitable power source include batteries, power grids, regenerative power supplies (e.g., wind power generators, photovoltaic cells, tidal energy generators), generators, and the like, and combinations thereof.

The potential difference can be applied to the electrochemical cells during at least a portion of the time that a gas mixture is exposed to the electrochemical cell. In an aspect, the potential difference can be applied prior to exposing the gas mixture to the electrochemical cell.

Application of a positive voltage to the electrochemical cell, during a charging mode, results in a redox reaction at the negative electrode wherein the electroactive polymer is reduced. As discussed herein, the electroactive polymer is selected for having a higher affinity for the target gas when it is in a reduced state relative to when it is in an oxidized state. By reducing the electroactive polymer and passing a gas mixture across the first electrode, the target gas can bond to the electroactive polymer. In this way the target gas can be removed from the gas mixture to provide a treated gas mixture (e.g., comprising a lesser amount of the target gas relative to the initial gas mixture).

The potential difference applied across the electrochemical cell, during the charge mode, can have a particular voltage. The potential difference applied across the electrochemical cell can depend, for example, on the reduction potential for the generation of at least one reduced state of the first electroactive species, as well as the standard potential for the interconversion between a reduced state and an oxidized state of the electroactive polymer in the second electrode. The voltage further includes the current multiplied by the stack electrochemical resistance. In an aspect, the potential difference is at least 0 V, or at least 0.1 V, or at least 0.2 V, or at least 0.5 V, or at least 0.8 V, or at least 1.0 V, or at least 1.5 V. In an aspect, the potential difference is less than or equal to 2.0 V, or less than or equal to 1.5 V, or less than or equal to 0.5 V, or less than or equal to 0.2 V.

In an aspect, for example when the electroactive polymer is according to Formula (IIa), the electroactive polymer can be reduced to at least one of its reduced states, for example, as shown below:

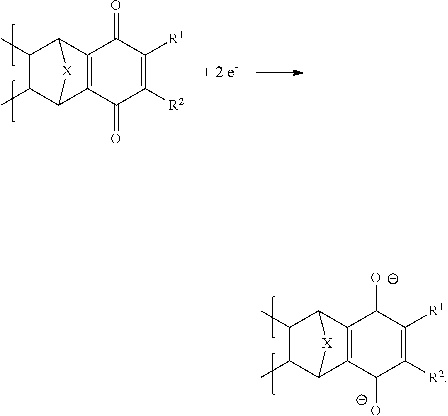

When the electroactive polymer is reduced in the presence of a target gas, for example carbon dioxide, the reduced form of the electroactive polymer can bond with the carbon dioxide:

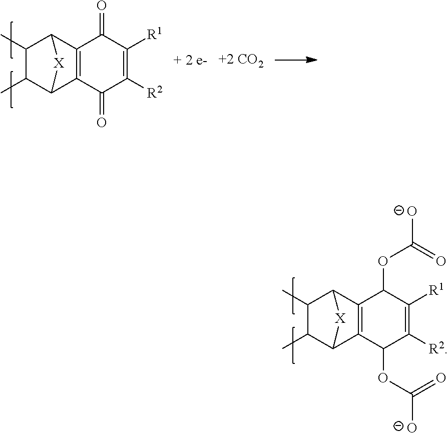

In an aspect, while the electroactive polymer is reduced at the first electrode, an electroactive species (e.g., a redox active polymer such as polyvinyl ferrocene) is being oxidized at the second electrode. During the charge mode, the oxidation of the electroactive species provides a source of electrons for driving the reduction of the electroactive polymer.

While the exemplary reaction shown above is shown taking place in one direction, it will be understood that some reversibility can be exhibited. Analogous reaction can take place with different electroactive species, as would be understood by a person of ordinary skill in the art.

In an aspect, a relatively large amount of the target gas is removed from the gas mixture during the processes described herein. Removing a relatively large amount of the target gas can, in some cases, be beneficial for any of a variety of applications, such as capturing gases that can be deleterious if released into the atmosphere for environmental reasons. For example, the target gas can comprise carbon dioxide, and removing a relatively high amount of the carbon dioxide from gas mixture can be beneficial to either limit the greenhouse gas impact of a process (e.g., an industrial process or transportation process) or to even reduce the amount of carbon dioxide in a room or the atmosphere (either for thermodynamic reasons for heating and air conditioning processes or for environmental reasons).

In an aspect the amount of target gas in a treated gas mixture (e.g., a gas mixture from which an amount of the target gas is removed upon being exposed to the electrochemical cell) is less than or equal to 50%, less than or equal to 25%, less than or equal to 10%, less than or equal to 5%, less than or equal to 2%, less than or equal to 1%, less than or equal to 0.5%, less than or equal to 0.1% of the amount (in volume percent) of the target gas in the original gas mixture prior to treatment (e.g., the amount of the target in the gas mixture prior to being exposed to electrochemical cell). In an aspect, the amount of target gas in a treated gas mixture is greater than or equal to 0.001%, greater than 0.005%, greater than or equal to 0.01%, greater than or equal to 0.05%, greater than or equal to 0.1%, greater than or equal to 0.5%, greater than or equal to 1%, greater than or equal to 2%, greater than or equal to 5% of the amount (in volume percent) of the target gas in the original gas mixture prior to treatment.

In an aspect, a second potential difference can be applied across the electrochemical cell after at least a portion of the target gas is bonded to the electroactive polymer. The second potential difference can be different than that first potential difference. In an aspect, applying the second potential difference results in a step of releasing a portion or all of the target gas bonded with the electroactive polymer to produce a second treated gas mixture. The second treated gas mixture can have a greater amount of the target gas than the input gas mixture. For example, target gas may be present in the second treated gas mixture in an amount such that its content is 10 volume percent (vol %), 20 vol %, 50 vol %, 100 vol %, 200 vol %, 1000 vol %, and/or up to 2,000 vol %, 5,000 vol %, 10,000 vol %, or more than the content in the first gas mixture.

The gas separation system can comprise an external circuit connecting the negative electrode and the positive electrode of each electrochemical cell to a power source configured to apply a potential difference across the negatives electrode and the positive electrode of each electrochemical cell. Each of the electrochemical cells of the gas separation system can be as described above. The electrochemical cells of the gas separation system can be stacked according to various configurations that are generally known in the art, including parallel or in series. In an aspect, the electroactive polymer can be dissolved in the electrolyte of the electrochemical cell, and the gas mixture can be in fluid contact with the electrolyte comprising the dissolved electroactive polymer during operation of the gas separation system. In an aspect, the electrochemical cells of the gas separation system need not be in direct contact with the gas mixture. In an aspect, a gas separation system can further comprise an absorber unit which can be in fluid contact with the gas mixture.

In an aspect, a gas separation system comprises a first set of electrochemical cells and a second set of electrochemical cells. Each of the first set and the second set can comprise one or more electrochemical cells as described throughout this disclosure. The first and second set can be made to run in parallel in an alternating fashion, such that one set of cells is operating in a charge mode and capturing a target gas (e.g., CO₂) from a gas mixture while another set of cells is operating in a discharge mode and releasing the target gas (e.g., CO₂). The system can comprise separate housings for each of the sets of electrochemical cells. The system can further comprise conduits and valving arranged to direct flow in a desired manner. The gas separation system can allow for nearly continuous separation of a gas mixture (e.g., gas stream), with the gas mixture being directed to the set of cells operating in a charge/capture mode, at a given moment, while a separate target gas-rich treated mixture is produced by the other set of cells operating in a discharge/release mode. Furthermore, additional sets of electrochemical cells may be added in parallel or in series, according to the needs of the application.

The gas mixture (e.g., a gas stream such as an input gas stream) can be introduced to the gas separation system at a particular flow rate. In an aspect, the flow rate can be greater than or equal to 0.001 liter per second (Us), greater than or equal to 0.005 L/s greater than or equal to 0.01, greater than or equal to 0.05 L/s, greater than or equal to 0.1 Us, greater than or equal to 0.5 L/s, greater than or equal to 1 L/s, greater than or equal to 5 L/s, greater than or equal to 10 L/s, greater than or equal to 50 L/s, or greater than or equal to 100 L/s. In an aspect, the flow rate of the gas mixture (e.g., a gas stream such as an input gas stream) can be less than or equal to 500 L/s, less than or equal to 400 L/s, less than or equal to 300 L/s, less than or equal to 200 L/s, less than or equal to 100 L/s, less than or equal to 50 L/s, less than or equal to 10 L/s, less than or equal to 1 L/s, less than or equal to 0.5 L/s, or less than or equal to 0.1 15 L/s. Suitable combinations of the foregoing ranges are mentioned.

In an aspect, during or after the step of releasing the target gas, the method further comprises applying a vacuum condition to the electrochemical cell to remove at least a portion or all of the released target gas from the electrochemical cell. One of ordinary skill, with the benefit of this disclosure, would understand suitable techniques and equipment for applying a vacuum condition to the electrochemical cell. For example, a vacuum pump can be fluidically connected to a gas outlet of the electrochemical cell. The vacuum pump can be operated to produce a negative pressure differential between the electrochemical cell bed and a downstream location. This vacuum condition can provide a force sufficient to cause target gas released during the releasing step described above to flow out of the electrochemical cell. The vacuum condition can be applied such that the pressure inside the electrochemical cell during or after the releasing of the target gas is less than or equal to 760 torr, less than or equal to 700 torr, less than or equal to 500 torr, less than or equal to 100 torr, less than or equal to 50 torr, less than or equal to 10 torr, and/or as low as 5 torr, as low as 1 torr, as low as 0.5 torr, as low as 0.1 torn.

In an aspect, the composite of the first electrode has a particular capacity for absorbing target gas (e.g., CO₂). For example, the composite can have an absorption capacity of at least 0.01 mole per square meter (mol per m²), at least 0.02 mol per m², at least 0.05 mol per m², or more. In an aspect, the composite can have an absorption capacity of less than or equal to 0.2 mol per m², less than or equal to 0.08 mol per m², less than or equal to 0.05 mol per m², less than or equal to 0.03 mol per m², or less. For example, the composite can have an absorption capacity of at least 0.01 mot per m² and less than or equal to 0.2 mol per m², or at least 0.02 mol per m² and less than or equal to 0.08 mol per m².

In an aspect the composite of the first electrode can have a particular surface area that is exposed to the gas mixture, for example, of greater than or equal to 5 cm², greater than or equal to 8 cm², greater than or equal to 10 cm², or up to 10 cm², up to 20 cm² or more.

Various components of a system, such as the electrodes (e.g., negative electrode, positive electrodes), power source, electrolyte, separator, container, circuitry, insulating material, and the like can be fabricated by those of ordinary skill in the art from any of a variety of components. Components can be molded, machined, extruded, pressed, isopressed, printed, infiltrated, coated, in green or fired states, or formed by any other suitable technique.

The electrodes described herein (e.g., negative electrode, positive electrodes) can be of any suitable size or shape. Non-limiting examples of shapes include sheets, cubes, cylinders, hollow tubes, spheres, and the like. The electrodes may be of any suitable size, depending on the application for which they are used (e.g., separating gases from ventilated air, direct air capture, etc.). Additionally, the electrode can comprise a means to connect the electrode to another electrode, a power source, and/or another electrical device. Those of ordinary skill in the art are readily aware of techniques for forming components of system herein.

Various electrical components of system may be in electrical communication with at least one other electrical component by a means for connecting. A means for connecting can be any material that allows the flow of electricity to occur between a first component and a second component. A non-limiting example of a means for connecting two electrical components is a wire comprising a conductive material (e.g., copper, silver, etc.). In an aspect, the system can comprise electrical connectors between two or more components (e.g., a wire and an electrode). In an aspect, a wire, electrical connector, or other means for connecting can be selected such that the resistance of the material is low. In an aspect, the resistances can be substantially less than the resistance of the electrodes, electrolyte, or other components of the system.

Electrochemical cells and gas separation systems of the present disclosure can further be as described in U.S. patent application Ser. No. 16/659,398, the contents of which is incorporated by reference in its entirety for all purposes.

The electrochemical cells, systems, and methods described herein can be implemented in a variety of applications. The number of electrochemical cells or sets of cells can be scaled to the requirements of a particular application as needed. The following aspects provide several non-limiting examples of applications. In an aspect, the systems and methods described herein can be for removing a target gas (e.g., CO₂) from ambient air, as well as enclosed spaces such as airtight building, car cabins—reducing the heating cost of incoming air for ventilation—and submarines and space capsules, where an increase in CO₂ levels could be catastrophic. In aspects directed to the electrical power industry, they can be used for capturing carbon dioxide post-combustion at varying concentrations. In an aspect, the systems and methods are suitable for separate target gases from industrial flue gas or industrial process gas. Also, they can be used for capturing sulfur dioxide and other gases from flue gas. In aspects directed to the oil and gas industry, the disclosed systems and methods can be used for capturing carbon dioxide and other gases from various processes and diverting them for downstream compression or processing. The disclosed systems and methods can be applied to capture carbon dioxide from burning natural gas used to heat the greenhouses in mild and cold climates, then diverting the captured dioxide into the greenhouse for the plants to use in photosynthesis, i.e., to feed the plants.

This disclosure is further illustrated by the following examples, which are non-limiting.

### Examples

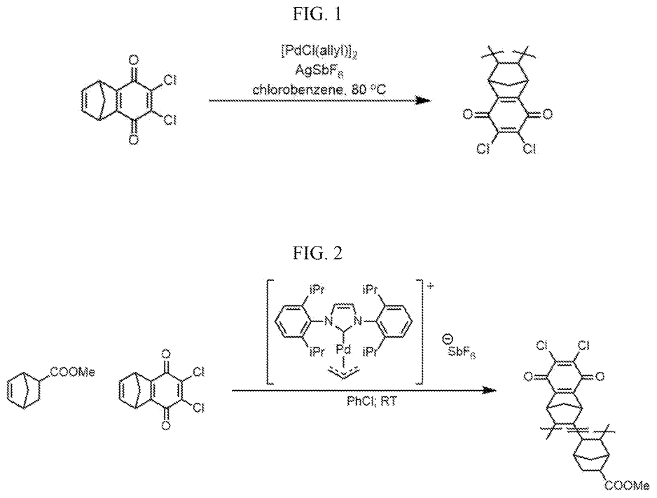

Example 1: A quinone-containing norbornene monomer was polymerized by insertion polymerization according to the chemical scheme shown in FIG. 1. In a nitrogen (N₂) glovebox, an oven-dried 500 milliliter (mL) two-neck flask with magnetic stirbar and stopcock gas adapter was charged with the quinone norbornene monomer (70 grams (g), 290 millimoles (mmol)), [PdCl(allyl)]₂ (530 milligrams (mg), 1.45 mmol, 2.90 mmol Pd), and anhydrous chlorobenzene (250 mL). In a separate oven-dried 2 dram septum cap vial, AgSbF₆ (1.1 g, 3.19 mmol) was dissolved in anhydrous chlorobenzene (4 mL). Both were sealed and removed from the glovebox, then placed under positive pressure of N₂ on a Schlenk line. The monomer/Pd solution was heated to 80° C. to fully dissolve the monomer, and the AgSbF₆ solution was then added to the reaction mixture by syringe. The temperature was maintained at 80° C., and the reaction was stirred for 24 hours (h). The reaction mixture was then allowed to cool to room temperature and was added slowly to rapidly stirring methanol (1.2 liters (L)). The resulting suspension was stirred for 15 minutes (min), then the precipitate was collected by vacuum filtration and washed with methanol and diethyl ether, then dried under reduced pressure to yield the product polymer as a brown powder (66 g, 94%). The polymer product was characterized by proton nuclear magnetic resonance (¹H-NMR) spectroscopy and weight average molecular weight (M_{w}) and number average molecular weight (M) were determined by gel permeation chromatography (GPC) eluting with tetrahydrofuran and relative to polystyrene standards. ¹H-NMR (CDCl₃): very broad signals centered at 3.62 and 1.83 ppm. GPC analysis (THF, polystyrene standards): M_{w} 4,400 grams per mole (g/mol), Mₙ 1,900 g/mol.

Example 2: A quinone-containing norbornene monomer was copolymerized with a carboxylic acid methyl ester-functionalized norbornene by insertion polymerization according to the chemical scheme shown in FIG. 2. In a N₂ glovebox, a fresh stock solution of catalyst was prepared by charging a dry 20 mL vial with NHC—PdCl(allyl) CX21 (CAS 478980-03-9, 120 mg, 210 micromoles (μmol)) and dry chlorobenzene (10 mL), then adding AgSbF₆ (110 mg, 320 μmol) and stirring 90 minutes. The resulting suspension was syringe filtered into a separate dry vial to give a catalyst solution at 21 umol Pd/mL.

In the N₂ glovebox, a dry 1 dram vial with stir bar was charged with quinone norbornene monomer (241 mg, 1.0 mmol) and 5-norbornene-2-carboxylic acid methyl ester (152 mg, 1.0 mmol), then 1 mL of the above freshly prepared catalyst solution was added. The monomers dissolved rapidly, and the reaction was stirred at room temperature in the glovebox for 24 h. After 24 h, the reaction mixture was a vibrant yellow-orange solution, which was removed from the glovebox and precipitated by addition to 10 mL of methanol. The resulting solid was collected by centrifugation, then resuspended in diethyl ether and centrifuged again to give the product as a bright yellow powder (190 mg, 48%). The polymer product was characterized by proton nuclear magnetic resonance (¹H-NMR) spectroscopy and weight average molecular weight (M_{w}) and number average molecular weight (Mₙ) were determined by gel permeation chromatography (GPC) eluting with tetrahydrofuran and relative to polystyrene standards. ¹H-NMR (CDCl₃⁻): broad, overlapping signals centered at 3.81, 3.67, 2.74, 2.36, 1.77, 1.61, 1.41 ppm. ¹H-NMR spectroscopy suggested the polymer product composition includes approximately 55% of repeating units derived from the 5-norbornene-2-carboxylic acid methyl ester, and approximately 45% of repeating units derived from the quinone-containing norbornene. sGPC analysis (THF, polystyrene standards): M_{w} 30,300 g/mol, Mₙ 10,800 g/mol.

This disclosure further encompasses the following aspects.
Aspect 1: An electroactive polymer comprising repeating units of Formula (I)

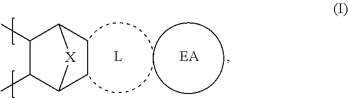

wherein X is —CH₂— or —O—; L is an optional fused C₄₋₆ cycloalkyl linking group or an optional fused benzene linking group; and EA is an electroactive species having an oxidized state, and at least one reduced state.
Aspect 2: The electroactive polymer of aspect 1, wherein the electroactive species is reactive towards a target species.
Aspect 3: The electroactive polymer of aspect 1 or 2, wherein the electroactive species is capable of bonding with a target species.
Aspect 4: The electroactive polymer of aspects 2 or 3, wherein the target species is a Lewis acid gas, and the at least one reduced state of the electroactive species is capable of forming an anion adduct between the Lewis acid gas and the reduced electroactive species.
Aspect 5: The electroactive polymer of any of aspects 1 to 4, wherein the electroactive species comprises a quinone or a pyrazine.
Aspect 6: The electroactive polymer of any of aspects 1 to 5, wherein the electroactive species comprises a quinone, and the electroactive polymer comprises repeating units of at least one of Formula (II) to (V)

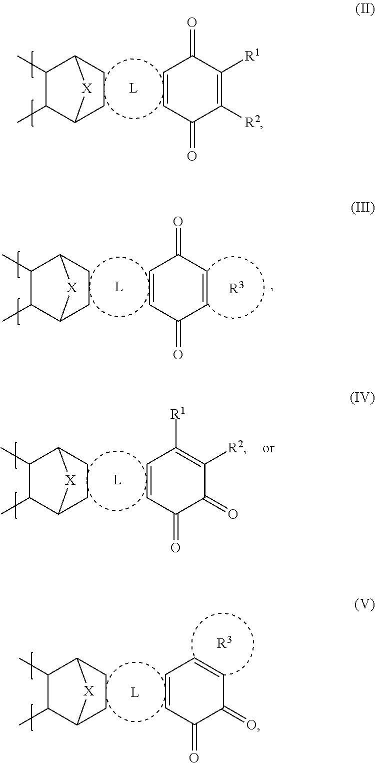

wherein X is —CH₂— or —O—; L is an optional fused C₄₋₆ cycloalkyl linking group or an optional fused benzene linking group; R¹ and R² are independently at each occurrence hydrogen, halogen, a substituted or unsubstituted C₁₋₆ alkyl group, a substituted or unsubstituted C₁₋₃₀ alkoxy group, a poly(C₁₋₃₀ alkylene oxide) group, a substituted or unsubstituted C₃₋₃₀ cycloalkyl group, a substituted or unsubstituted C₆₋₃₀ aryl group, a substituted or unsubstituted C₆₋₃₀ heteroaryl group, a nitrile group, a nitro group, a thiol group, an amine group, an amide group, an ester group, or a ketone group; and R³ is a fused substituted or unsubstituted aryl group.
Aspect 7: The electroactive polymer of aspect 6, wherein L is not present, and the electroactive polymer comprises repeating units of at least one of Formula (IIa) to (Va)

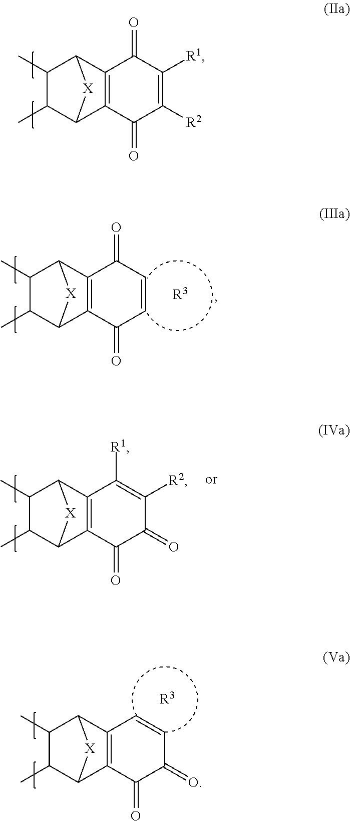

Aspect 8: The electroactive polymer of aspect 7, comprising repeating units according to Formula (IIa), wherein R¹ and R² are each hydrogen.
Aspect 9: The electroactive polymer of aspect 7, comprising repeating units according to Formula (IIa), wherein R¹ and R² are each methyl.
Aspect 10: The electroactive polymer of aspect 7, comprising repeating units according to Formula (IIIa), wherein R³ is a substituted or unsubstituted fused benzene group.
Aspect 11: The electroactive polymer of aspect 7, comprising repeating units according to Formula (IIIa), wherein R³ is a substituted or unsubstituted fused napthyl group.
Aspect 12: The electroactive polymer of aspect 6, wherein L is present, preferably wherein L is a fused cyclobutene group or a fused benzene group.
Aspect 13: The electroactive polymer of any of aspects 1 to 5, wherein the electroactive species comprises a pyrazine, and the electroactive polymer comprises repeating units of at least one of Formula (VI) to (VII)

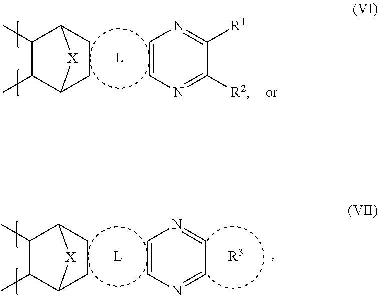

wherein X is —CH₂— or —O—; L is an optional fused C₄₋₆ cycloalkyl linking group or an optional fused benzene linking group; R¹ and R² are independently at each occurrence hydrogen, halogen, a substituted or unsubstituted C₁₋₆ alkyl group, a substituted or unsubstituted C₁₋₃₀ alkoxy group, a poly(C₁₋₃₀ alkylene oxide) group, a substituted or unsubstituted C₃₋₃₀ cycloalkyl group, a substituted or unsubstituted C₆₋₃₀ aryl group, a substituted or unsubstituted C₆₋₃₀ heteroaryl group, a nitrile group, a nitro group, a thiol group, an amine group, an amide group, an ester group, or a ketone group; and R³ is a fused substituted or unsubstituted aryl group.
Aspect 14: The electroactive polymer of aspect 13, wherein L is not present, and the electroactive polymer comprises repeating units of at least one of Formula (VIa) to (VIIa)

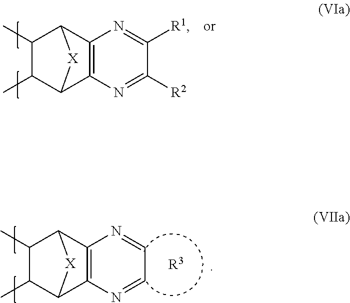

Aspect 15: The electroactive polymer of aspect 14, comprising repeating units according to Formula (VIa), wherein R¹ and R² are each hydrogen.
Aspect 16: The electroactive polymer of aspect 14, comprising repeating units according to Formula (VIa), wherein R¹ and R² are each a nitrile group.
Aspect 17; The electroactive polymer of aspect 14, comprising repeating units according to Formula (VIa), wherein R¹ and R² are each a substituted or unsubstituted phenyl group.
Aspect 18: The electroactive polymer of aspect 14, comprising repeating units according to Formula (VIIa), wherein R is a substituted or unsubstituted fused benzene group.
Aspect 19: The electroactive polymer of any of aspects 1 to 18, wherein X is —CH₂—.
Aspect 20: The electroactive polymer of any of aspects 1 to 18, wherein X is —O—.
Aspect 21: The electroactive polymer of any of aspects 1 to 20, wherein the electroactive polymer is a copolymer further comprising one or more repeating units different from the repeating units according to Formula (I).
Aspect 22; The electroactive polymer of aspect 21, further comprising one or more repeating units comprising a crosslinkable group, an adhesion promoting group, a solubilizing group, or a combination thereof.
Aspect 23: The electroactive polymer of any of aspects 1 to 22, further comprising repeating units derived from ethylene, an alpha olefin, an acrylate, an acrylamide, a methacrylate, a methacrylamide, acrylonitrile, a vinyl monomer or a combination thereof, preferably ethylene or propylene.
Aspect 24: The electroactive polymer of any of aspects 1 to 23, wherein the electroactive polymer comprises at least 5 repeating units according to Formula (I).
Aspect 25; A method of making an electroactive polymer, the method comprising: polymerizing an electroactive monomer of Formula (XIV)

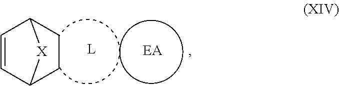

under conditions effective to provide an electroactive polymer comprising repeating units of Formula (I)

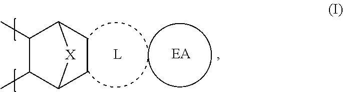

wherein in the foregoing Formulas, X is —CH₂— or —O—; L is an optional fused C₄₋₆ cycloalkyl linking group or an optional fused benzene linking group; and EA is an electroactive species having an oxidized state, and at least one reduced state.
Aspect 26: The method of aspect 25, wherein the polymerizing is in the presence of a free radical initiator.
Aspect 27: The method of aspect 25, wherein the polymerizing is in the presence of a palladium or a nickel catalyst.
Aspect 28: The method of any of aspects 25 to 27, wherein the conditions effective to provide the electroactive polymer comprise a time of 1 to 72 hours and a temperature of 20° C. or more, preferably 20 to 100° C.
Aspect 29: A composite comprising the electroactive polymer of any of aspects 1 to 28.
Aspect 30: The composite of aspect 29, wherein the substrate comprises a carbonaceous material.
Aspect 31: The composite of aspects 29 or 30, wherein the electroactive polymer is at least partially crosslinked.
Aspect 32: An electrode assembly comprising: a porous separator; and the composite of any of aspects 29 to 31 on a surface of the porous separator, in a pore of the porous separator, or a combination thereof.
Aspect 33: An electrode assembly comprising: a current collector; and the composite of any of aspects 29 to 31 on a surface of the current collector.
Aspect 34: An electrochemical cell comprising the composite of any of aspects 29 to 31.
Aspect 35: An electrochemical cell, comprising: a first electrode comprising the composite of any of aspects 28 to 31; a second electrode comprising a complementary electroactive layer; and a first separator between the first electrode and the second electrode.
Aspect 36: The electrochemical cell of aspect 35, wherein the composite further comprises an electrolyte.
Aspect 37: A gas separation system comprising a plurality of electrochemical cells in fluid communication with a gas inlet and a gas outlet, wherein each of the plurality of electrochemical cells is according to any of aspects 34 to 36.
Aspect 38: The gas separation system of aspect 37, wherein the gas separation system further comprises a contactor unit in fluid contact with a gas mixture.
Aspect 39: The gas separation system of aspect 38, wherein the contactor unit is in fluid communication with an electrolyte.
Aspect 40: An electrochemical cell comprising the electroactive polymer of any of aspects 1 to 24.
Aspect 41: The electrochemical cell of aspect 40, comprising: a first electrode; a second electrode; a separator between the first electrode and the second electrode; and an electrolyte contacting at least one of the first electrode or the second electrode, wherein at least one of the first electrode, the second electrode, or the electrolyte comprises the electroactive polymer.
Aspect 42: The electrochemical cell of aspect 41, wherein the electrolyte comprises the electroactive polymer.
Aspect 43: A gas separation system comprising: the electrochemical cell according to aspect 42, wherein the electrochemical cell is in fluid communication with a gas inlet and a gas outlet, and the electrolyte comprising the electroactive polymer is in fluid contact with a gas mixture.
Aspect 44: The gas separation system of aspect 43, further comprising a contactor unit separate from the electrochemical cell and in which the electrolyte contacts the gas mixture.
Aspect 45: The gas separation system of aspect 44, wherein the contactor unit comprises a gas adsorber, a gas absorber, or a combination thereof.
Aspect 46: The gas separation system of any of aspects 43 to 45, comprising a plurality of the electrochemical cells.
Aspect 47: An energy storage device comprising the electroactive polymer of any of aspects 1 to 24.
Aspect 48: An energy storage device comprising the composite of any of aspects 28 to 31.
Aspect 49: The energy storage device of aspect 48, comprising a plurality of the electrochemical cells.
Aspect 50: An energy storage device comprising the electrochemical cell of any of aspects 34 to 36 or 40 to 42.
Aspect 51: An electrochromic device comprising the electroactive polymer of any of aspects 1 to 24.
Aspect 52: An electrochromic device comprising the composite of any of aspects 28 to 31.
Aspect 53: An electrochromic device comprising the electrochemical cell of aspects 34 to 36 or 40 to 42.
Aspect 54: A method for separating a target gas from a fluid mixture comprising the target gas, the method comprising: contacting the fluid mixture with an electroactive polymer comprising repeating units according to Formula (I), wherein the electroactive polymer is in a reduced state, to form an anion adduct between the target gas and the electroactive polymer in the reduced state.

The compositions, methods, and articles can alternatively comprise, consist of, or consist essentially of, any appropriate materials, steps, or components herein disclosed. The compositions, methods, and articles can additionally, or alternatively, be formulated so as to be devoid, or substantially free, of any materials (or species), steps, or components, that are otherwise not necessary to the achievement of the function or objectives of the compositions, methods, and articles.

All ranges disclosed herein are inclusive of the endpoints, and the endpoints are independently combinable with each other. “Combinations” is inclusive of blends, mixtures, alloys, reaction products, and the like. The terms “first,” “second,” and the like, do not denote any order, quantity, or importance, but rather are used to distinguish one element from another. The terms “a” and “an” and “the” do not denote a limitation of quantity, and are to be construed to cover both the singular and the plural, unless otherwise indicated herein or clearly contradicted by context. “Or” means “and/or” unless clearly stated otherwise. Reference throughout the specification to “an aspect” means that a particular element described in connection with the aspect is included in at least one aspect described herein, and may or may not be present in other aspects. The term “combination thereof” as used herein includes one or more of the listed elements, and is open, allowing the presence of one or more like elements not named. In addition, it is to be understood that the described elements may be combined in any suitable manner in the various aspects.

Unless specified to the contrary herein, all test standards are the most recent standard in effect as of the filing date of this application, or, if priority is claimed, the filing date of the earliest priority application in which the test standard appears.

Unless defined otherwise, technical and scientific terms used herein have the same meaning as is commonly understood by one of skill in the art to which this application belongs. All cited patents, patent applications, and other references are incorporated herein by reference in their entirety. However, if a term in the present application contradicts or conflicts with a term in the incorporated reference, the term from the present application takes precedence over the conflicting term from the incorporated reference.

Compounds are described using standard nomenclature. For example, any position not substituted by any indicated group is understood to have its valency filled by a bond as indicated, or a hydrogen atom. A dash (“—”) that is not between two letters or symbols is used to indicate a point of attachment for a substituent. For example, —CHO is attached through carbon of the carbonyl group.

Unless substituents are otherwise specifically indicated, each of the foregoing groups can be unsubstituted or substituted, provided that the substitution does not significantly adversely affect synthesis, stability, or use of the compound. “Substituted” means that the compound, group, or atom is substituted with at least one (e.g., 1, 2, 3, or 4) substituents instead of hydrogen, where each substituent is independently nitro (—NO₂), cyano (—CN), hydroxy (—OH), halogen, thiol (—SH), thiocyano (—SCN), C₁₋₆ alkyl, C₂₋₆ alkenyl, C₂₋₆ alkynyl, C₁₋₆ haloalkyl, C₁₋₉ alkoxy, C₁₋₆ haloalkoxy, C₃₋₁₂ cycloalkyl, C₅₋₁₈ cycloalkenyl, C₆₋₁₂ aryl, C₇₋₁₃ arylalkylene (e.g., benzyl), C₇₋₁₂ alkylarylene (e.g., toluyl), C₄₋₁₂ heterocycloalkyl, C₃₋₁₂ heteroaryl, C₁₋₆ alkyl sulfonyl (—S(═O)₂-alkyl), C₆₋₁₂ arylsulfonyl (—S(═O)₂-aryl), or tosyl (CH₃C₆H₄SO₂—), provided that the substituted atom's normal valence is not exceeded, and that the substitution does not significantly adversely affect the manufacture, stability, or desired property of the compound. When a compound is substituted, the indicated number of carbon atoms is the total number of carbon atoms in the compound or group, including those of any substituents.

While particular embodiments have been described, alternatives, modifications, variations, improvements, and substantial equivalents that are or may be presently unforeseen may arise to applicants or others skilled in the art. Accordingly, the appended claims as filed and as they may be amended are intended to embrace all such alternatives, modifications variations, improvements, and substantial equivalents.

1. An electroactive polymer comprising repeating units of Formula (I) 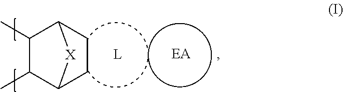
wherein
X is —CH₂— or —O—;
L is an optional fused C₄₋₆ cycloalkyl linking group or an optional fused benzene linking group; and
EA is an electroactive species having
at least one oxidized state, and
at least one reduced state.

2. The electroactive polymer of claim 1, wherein the electroactive species is reactive towards a target species or wherein the electroactive species is capable of bonding with a target species.

3. (canceled)

4. The electroactive polymer of claim 2, wherein the target species is a Lewis acid gas, and the at least one reduced state of the electroactive species is capable of forming an anion adduct between the Lewis acid gas and the reduced electroactive species.

5. (canceled)

6. The electroactive polymer of claim 1, wherein the electroactive species comprises a quinone, and the electroactive polymer comprises repeating units of at least one of Formula (II) to (V) 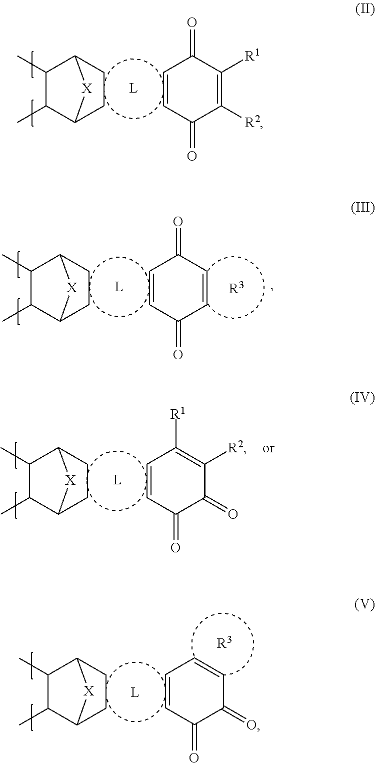
wherein
X is —CH₂— or —O—;
L is an optional fused C₄₋₆ cycloalkyl linking group or an optional fused benzene linking group;
R¹ and R² are independently at each occurrence hydrogen, halogen, a substituted or unsubstituted C₁₋₆ alkyl group, a substituted or unsubstituted C₁₋₃₀ alkoxy group, a poly(C₁₋₃₀ alkylene oxide) group, a substituted or unsubstituted C₃₋₃₀ cycloalkyl group, a substituted or unsubstituted C₆₋₃₀ aryl group, a substituted or unsubstituted C₆₋₃₀ heteroaryl group, a nitrile group, a nitro group, a thiol group, an amine group, an amide group, an ester group, or a ketone group; and
R³ is a fused substituted or unsubstituted aryl group.

7. The electroactive polymer of claim 6, wherein L is not present, and the electroactive polymer comprises repeating units of at least one of Formula (IIa) to (Va)

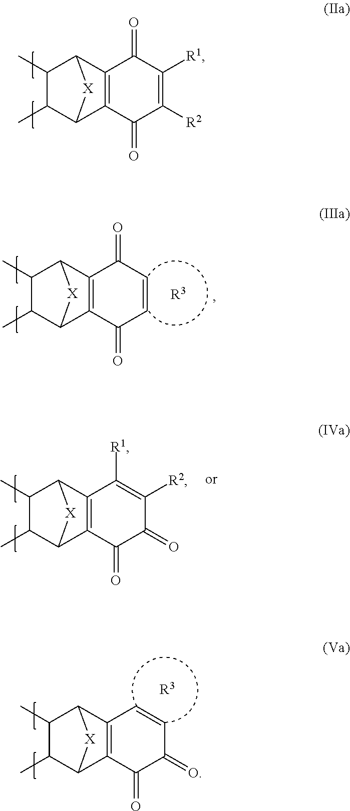

8. The electroactive polymer of claim 7, comprising repeating units according to Formula (IIa), wherein
R¹ and R² are each hydrogen; or
R¹ and R² are each methyl; or
repeating units according to Formula (IIIa), wherein
R³ is a substituted or unsubstituted fused benzene group; or
R³ is a substituted or unsubstituted fused napthyl group.

9. (canceled)

10. (canceled)

11. (canceled)

12. The electroactive polymer of claim 6, wherein L is present and is a fused cyclobutene group or a fused benzene group.

13. The electroactive polymer of claim 1, wherein the electroactive species comprises a pyrazine, and the electroactive polymer comprises repeating units of at least one of Formula (VI) to (VII) 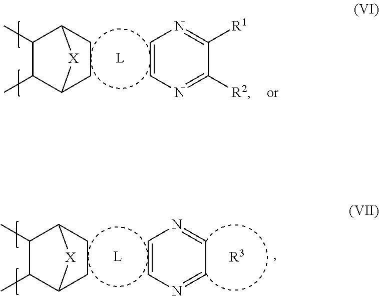
wherein
X is —CH₂— or —O—;
L is an optional fused C₄₋₆ cycloalkyl linking group or an optional fused benzene linking group;
R¹ and R² are independently at each occurrence hydrogen, halogen, a substituted or unsubstituted C₁₋₆ alkyl group, a substituted or unsubstituted C₁₋₃₀ alkoxy group, a poly(C₁₋₃₀ alkylene oxide) group, a substituted or unsubstituted C₃₋₃₀ cycloalkyl group, a substituted or unsubstituted C₆₋₃₀ aryl group, a substituted or unsubstituted C₆₋₃₀ heteroaryl group, a nitrile group, a nitro group, a thiol group, an amine group, an amide group, an ester group, or a ketone group; and
R³ is a fused substituted or unsubstituted aryl group.

14. The electroactive polymer of claim 13, wherein L is not present, and the electroactive polymer comprises repeating units of at least one of Formula (VIa) to (VIIa)

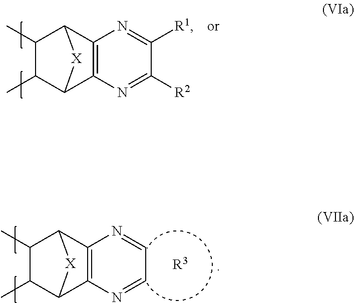

15. The electroactive polymer of claim 14, comprising repeating units according to Formula (VIa), wherein
R¹ and R² are each hydrogen; or
R¹ and R² are each a nitrile group; or
R¹ and R² are each a substituted or unsubstituted phenyl group; or
repeating units according to Formula (VIIa), wherein
R³ is a substituted or unsubstituted fused benzene group.

16. (canceled)

17. (canceled)

18. (canceled)

19. The electroactive polymer of claim 1, wherein X is —CH₂—.

20. The electroactive polymer of claim 1, wherein X is —O—.

21. The electroactive polymer of claim 1, wherein the electroactive polymer is a copolymer further comprising
one or more repeating units different from the repeating units according to Formula (I); or
one or more repeating units comprising a crosslinkable group, an adhesion promoting group, a solubilizing group, or a combination thereof.

22. (canceled)

23. (canceled)

24. (canceled)

25. A method of making an electroactive polymer, the method comprising:
polymerizing an electroactive monomer of Formula (XIV) 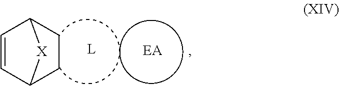
under conditions effective to provide an electroactive polymer comprising repeating units of Formula (I) 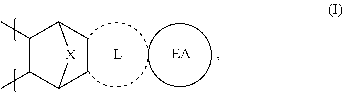
wherein in the foregoing Formulas,
X is —CH₂— or —O—;
L is an optional fused C₄₋₆ cycloalkyl linking group or an optional fused benzene linking group; and
EA is an electroactive species having
an oxidized state, and
at least one reduced state.

26. The method of claim 25, wherein the polymerizing is in the presence of a free radical initiator or a palladium or a nickel catalyst and wherein the conditions effective to provide the electroactive polymer comprise a time of 1 to 72 hours and a temperature of 20° C. or more.

27. (canceled)

28. (canceled)

29. A composite comprising the electroactive polymer of claim 1, optionally wherein
the substrate comprises a carbonaceous material; or
the electroactive polymer is at least partially crosslinked.

30. (canceled)

31. (canceled)

32. An electrode assembly comprising:
a porous separator; and
the composite of claim 29 on a surface of the porous separator, in a pore of the porous separator, or a combination thereof.

33. An electrode assembly comprising:
a current collector; and
the composite of claim 29 on a surface of the current collector.

34. (canceled)

35. (canceled)

36. (canceled)

37. A gas separation system comprising a plurality of electrochemical cells in fluid communication with a gas inlet and a gas outlet, wherein each of the plurality of electrochemical cells is according to claim 34, wherein the gas separation system optionally further comprises a contactor unit in fluid contact with a gas mixture, wherein the contactor unit is in fluid communication with an electrolyte.

38. (canceled)

39. (canceled)

40. An electrochemical cell comprising the electroactive polymer of claim 1, the electrochemical cell comprising:
a first electrode;
a second electrode;
a separator between the first electrode and the second electrode; and
an electrolyte contacting at least one of the first electrode or the second electrode,
wherein at least one of the first electrode, the second electrode, or the electrolyte comprises the electroactive polymer.

41. (canceled)

42. (canceled)

43. A gas separation system comprising: a plurality of electrochemical cells, wherein each electrochemical cell is according to claim 42, wherein the electrochemical cell is in fluid communication with a gas inlet and a gas outlet, and the electrolyte comprising the electroactive polymer is in fluid contact with a gas mixture, wherein the gas separation system optionally further comprises a contactor unit separate from the electrochemical cell and in which the electrolyte contacts the gas mixture, wherein the contactor unit comprises a gas adsorber, a gas absorber, or a combination thereof.

44. (canceled)

45. (canceled)

46. (canceled)

47. An energy storage device or an electrochromic device comprising the electroactive polymer of claim 1, optionally comprising a plurality of the electrochemical cells.

48. (canceled)

49. (canceled)

50. (canceled)

51. (canceled)

52. (canceled)

53. (canceled)

54. A method for separating a target gas from a fluid mixture comprising the target gas, the method comprising:
contacting the fluid mixture with an electroactive polymer comprising repeating units according to Formula (I), 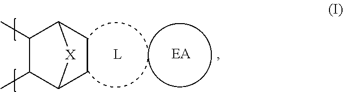
wherein
X is —CH₂— or —O—;
L is an optional fused C₄₋₆ cycloalkyl linking group or an optional fused benzene linking group; and
EA is an electroactive species having
at least one oxidized state, and
at least one reduced state;
wherein the electroactive polymer is in a reduced state, to form an anion adduct between the target gas and the electroactive polymer in the reduced state to separate the target gas from the fluid mixture.
